(19) United States
(12) Patent Application Publication
(10) Pub. No.: US 2026/0068344 A1
(43) Pub. Date: Mar. 5, 2026

(54) PHOTODETECTOR AND ELECTRONIC APPARATUS

(71) Applicant: SONY SEMICONDUCTOR SOLUTIONS CORPORATION, KANAGAWA (JP)

(72) Inventors: TAKAAKI SOEDA, KANAGAWA (JP); MAHO WATANABE, KANAGAWA (JP)

(21) Appl. No.: 19/108,192

(22) PCT Filed: Aug. 3, 2023
(86) PCT No.: PCT/JP2023/028395

§ 371 Date: Mar. 3, 2025

(30) Foreign Application Priority Data
Sep. 9, 2022 (JP) 2022-143430

(51) Int. Cl. H10F 39/00; H04N 25/767; H04N 25/78; H10F 39/18

(52) U.S. Cl. CPC H10F 39/8063; H10F 39/182; H10F 39/8053; H10F 39/811; H04N 25/767; H04N 25/78

(57) ABSTRACT

A photodetector according to one embodiment of the present disclosure includes: a semiconductor substrate having a first surface and a second surface opposed to each other, and including a plurality of pixels and a photoelectric converter, the plurality of pixels arranged in a matrix, and the photoelectric converter that is formed for each of the pixels to be embedded in the semiconductor substrate, and generates an electric charge corresponding to an amount of received light by photoelectric conversion; a microlens disposed on side of the first surface to extend over adjacent pixels of the plurality of pixels; and a plurality of scatterers having different indices, the plurality of scatterers stacked in a collection optical path of the microlens.

### TECHNICAL FIELD

The present disclosure relates, for example, to a photodetector and an electronic apparatus that make it possible to obtain imaging information and parallax information.

### BACKGROUND ART

For example, PTL 1 discloses a solid-state imaging device that includes an incident light scatterer to thereby correct deviation in light reception sensitivity caused by a manufacturing error between a phase-difference detection pixel pair. The incident light scatterer is provided in an optical path linking a center position of a pupil division microlens provided for every multiple pixels and a pixel boundary portion between multiple phase-difference detection pixels provided with the pupil division microlens and in an intermediate layer between the pupil division microlens and a light-receiving surface of a semiconductor substrate.

### CITATION LIST

### Patent Literature

PTL 1: Japanese Unexamined Patent Application Publication No. 2013-211413

### SUMMARY OF THE INVENTION

Incidentally, in a photodetector that makes it possible to obtain imaging information and parallax information, suppression of color mixture is desired together with correction of deviation in a sensitivity difference between multiple pixels sharing a microlens.

It is desirable to provide a photodetector and an electronic apparatus that make it possible to suppress color mixture while correcting deviation in a sensitivity difference between multiple pixels sharing a microlens.

A photodetector according to one embodiment of the present disclosure includes: a semiconductor substrate having a first surface and a second surface opposed to each other, and including a plurality of pixels and a photoelectric converter, the plurality of pixels arranged in a matrix, and the photoelectric converter that is formed for each of the pixels to be embedded in the semiconductor substrate, and generates an electric charge corresponding to an amount of received light by photoelectric conversion; a microlens disposed on side of the first surface to extend over adjacent pixels of the plurality of pixels; and a plurality of scatterers having different indices, the plurality of scatterers stacked in a collection optical path of the microlens.

An electronic apparatus according to one embodiment of the present disclosure includes the photodetector according to one embodiment described above.

In the photodetector according to one embodiment of the present disclosure and the electronic apparatus according to one embodiment of the present disclosure, the microlens disposed to extend over the adjacent pixels of the plurality of pixels is provided on side of a light-receiving surface (the first surface) of the semiconductor substrate that includes the plurality of pixels arranged in a matrix and the photoelectric converter for each pixel, and the plurality of scatterers having different refractive indices is stacked in the collection optical path of the microlens. This suppresses strong scattering of incident light by the scatterer.

### BRIEF DESCRIPTION OF DRAWINGS

FIG. 1 is an explanatory diagram of an overview of the present technology.

FIG. 2 is a schematic cross-sectional diagram illustrating an example of a configuration of a photodetector according to one embodiment of the present disclosure.

FIG. 3 is a block diagram illustrating an overall configuration of the photodetector illustrated in FIG. 2.

FIG. 4 is an equivalent circuit diagram of a unit-pixel unit illustrated in FIG. 2.

FIG. 5 is a schematic plan diagram illustrating an example of a configuration of the unit-pixel unit illustrated in FIG. 2.

FIG. 6 is a schematic plan diagram illustrating another example of the configuration of the unit-pixel unit illustrated in FIG. 2.

FIG. 7 is a schematic cross-sectional diagram illustrating an example of shift of a color filter layer and a microlens illustrated in FIG. 2.

FIG. 8A is a schematic cross-sectional diagram for describing an example of a method of manufacturing a scattering film illustrated in FIG. 2.

FIG. 8B is a schematic cross-sectional diagram illustrating a process subsequent to FIG. 8A.

FIG. 8C is a schematic cross-sectional diagram illustrating a process subsequent to FIG. 8B.

FIG. 8D is a schematic cross-sectional diagram illustrating a process subsequent to FIG. 8C.

FIG. 8E is a schematic cross-sectional diagram illustrating a process subsequent to FIG. 8D.

FIG. 9A is a schematic cross-sectional diagram for describing another example of the method of manufacturing the scattering film illustrated in FIG. 2.

FIG. 9B is a schematic cross-sectional diagram illustrating a process subsequent to FIG. 9A.

FIG. 9C is a schematic cross-sectional diagram illustrating a process subsequent to FIG. 9B.

FIG. 9D is a schematic cross-sectional diagram illustrating a process subsequent to FIG. 9C.

FIG. 9E is a schematic cross-sectional diagram illustrating a process subsequent to FIG. 9D.

FIG. 9F is a schematic cross-sectional diagram illustrating a process subsequent to FIG. 9E.

FIG. 10 is a schematic cross-sectional diagram illustrating an example of a configuration of a photodetector according to Modification Example 1 of the present disclosure.

FIG. 11 is a schematic cross-sectional diagram illustrating an example of a configuration of a photodetector according to Modification Example 2 of the present disclosure.

FIG. 12 is a schematic cross-sectional diagram illustrating an example of a configuration of a photodetector according to Modification Example 3 of the present disclosure.

FIG. 13 is a schematic cross-sectional diagram illustrating an example of a configuration of a photodetector according to Modification Example 4 of the present disclosure.

FIG. 14 is a schematic cross-sectional diagram illustrating an example of a configuration of a photodetector according to Modification Example 5 of the present disclosure.

FIG. 15 is a schematic cross-sectional diagram illustrating another example of the configuration of the photodetector according to Modification Example 5 of the present disclosure.

FIG. 16 is a schematic cross-sectional diagram illustrating an example of a configuration of a photodetector according to Modification Example 6 of the present disclosure.

FIG. 17 is a schematic cross-sectional diagram illustrating another example of the configuration of the photodetector according to Modification Example 6 of the present disclosure.

FIG. 18 is a schematic plan diagram illustrating an example of a configuration of a unit-pixel unit of the photodetector according to Modification Example 6 of the present disclosure.

FIG. 19 is a schematic plan diagram illustrating another example of the configuration of the unit-pixel unit of the photodetector according to Modification Example 6 of the present disclosure.

FIG. 20 is a schematic plan diagram illustrating another example of the configuration of the unit-pixel unit of the photodetector according to Modification Example 6 of the present disclosure.

FIG. 21 is a schematic cross-sectional diagram illustrating an example of a configuration of a photodetector according to Modification Example 7 of the present disclosure.

FIG. 22 is a schematic cross-sectional diagram illustrating an example of a configuration of a photodetector according to Modification Example 8 of the present disclosure.

FIG. 23 is a schematic cross-sectional diagram illustrating another example of the configuration of the photodetector according to Modification Example 8 of the present disclosure.

FIG. 24 is a schematic cross-sectional diagram illustrating another example of the configuration of the photodetector according to Modification Example 8 of the present disclosure.

FIG. 25 is a schematic cross-sectional diagram illustrating an example of a configuration of a photodetector according to Modification Example 9 of the present disclosure.

FIG. 26 is a schematic cross-sectional diagram illustrating an example of a configuration of a photodetector according to Modification Example 10 of the present disclosure.

FIG. 27 is a schematic cross-sectional diagram illustrating another example of the configuration of the photodetector according to Modification Example 10 of the present disclosure.

FIG. 28A is a schematic diagram illustrating an example of an overall configuration of a photodetection system using the photodetector illustrated in FIG. 2.

FIG. 28B is a diagram illustrating an example of a circuit configuration of the photodetection system illustrated in FIG. 28A.

FIG. 29 is a block diagram depicting an example of schematic configuration of a vehicle control system.

FIG. 30 is a diagram of assistance in explaining an example of installation positions of an outside-vehicle information detecting section and an imaging section.

FIG. 31 is a view depicting an example of a schematic configuration of an endoscopic surgery system.

FIG. 32 is a block diagram depicting an example of a functional configuration of a camera head and a camera control unit (CCU).

FIG. 33 is a schematic plan diagram illustrating an example of a configuration of a photodetector according to Modification Example 11 of the present disclosure.

FIG. 34 is a schematic plan diagram illustrating another example of the configuration of the photodetector according to Modification Example 11 of the present disclosure.

FIG. 35 is a schematic plan diagram illustrating another example of the configuration of the photodetector according to Modification Example 11 of the present disclosure.

FIG. 36 is a schematic plan diagram illustrating an example of a configuration of a photodetector according to Modification Example 12 of the present disclosure.

FIG. 37 is a schematic plan diagram illustrating another example of the configuration of the photodetector according to Modification Example 12 of the present disclosure.

FIG. 38 is a schematic plan diagram illustrating another example of the configuration of the photodetector according to Modification Example 12 of the present disclosure.

FIG. 39 is a schematic plan diagram illustrating an example of a configuration of a photodetector according to Modification Example 13 of the present disclosure.

FIG. 40 is a schematic plan diagram illustrating another example of the configuration of the photodetector according to Modification Example 13 of the present disclosure.

FIG. 41 is a schematic plan diagram illustrating another example of the configuration of the photodetector according to Modification Example 13 of the present disclosure.

FIG. 42 is a schematic plan diagram illustrating arrangement of color filters (A) and an example of configurations of separation sections (B) in a photodetector according to Modification Example 14 of the present disclosure.

### MODES FOR CARRYING OUT THE INVENTION

Some embodiments of the present disclosure are described below in detail with reference to the drawings. The following description is a specific example of the present disclosure, and the present disclosure is not limited to the following embodiments. In addition, the present disclosure is not limited to arrangements, dimensions, dimension ratios, etc. of respective components illustrated in each drawing. It is to be noted that description is given in the following order.
1. Embodiment (An example of a photodetector in which, in multiple pixels sharing a microlens, a plurality of scatterers having different refractive indices is stacked in a collection optical path of the microlens)
2. Modification Examples
2-1. Modification Example 1 (Another example of a configuration of the photodetector)
2-2. Modification Example 2 (Another example of the configuration of the photodetector)
2-3. Modification Example 3 (Another example of the configuration of the photodetector)
2-4. Modification Example 4 (Another example of the configuration of the photodetector)
2-5. Modification Example 5 (Another example of the configuration of the photodetector)
2-6. Modification Example 6 (Another example of the configuration of the photodetector)
2-7. Modification Example 7 (Another example of the configuration of the photodetector)
2-8. Modification Example 8 (Another example of the configuration of the photodetector)
2-9. Modification Example 9 (Another example of the configuration of the photodetector)
2-10. Modification Example 10 (Another example of the configuration of the photodetector)
2-11. Modification Example 11 (Another example of the configuration of the photodetector)
2-12. Modification Example 12 (Another example of the configuration of the photodetector)
2-13. Modification Example 13 (Another example of the configuration of the photodetector)
2-14. Modification Example 14 (Another example of the configuration of the photodetector)
3. Application Example
4. Practical Application Examples

### 1. EMBODIMENT

### Overview

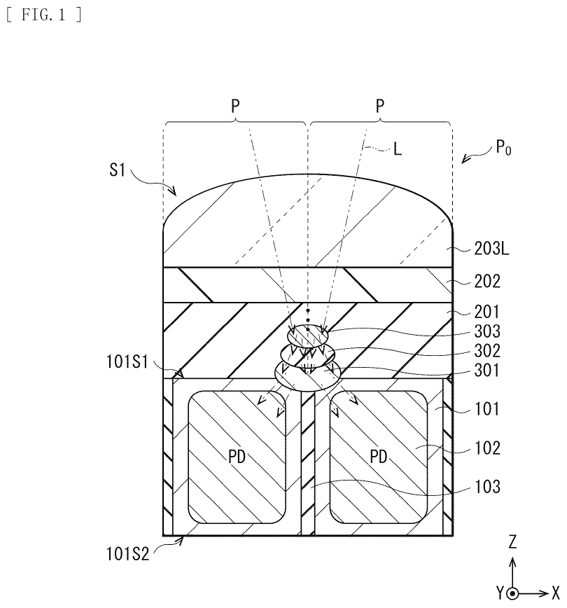

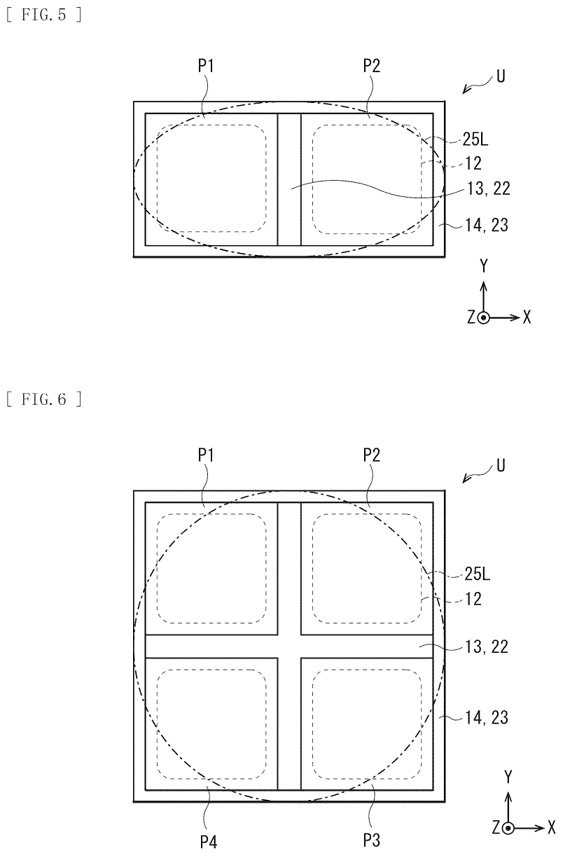

FIG. 1 schematically illustrates a cross-sectional configuration of an image-plane phase-difference pixel P₀ that generates a signal for phase-difference detection for description of an overview of the present technology. The image-plane phase-difference pixel P₀ according to the present embodiment constitutes a photodetector 1 to be described later. The photodetector 1 makes it possible to obtain, for example, imaging information and parallax information at the same time. The image-plane phase-difference pixel P₀ includes a pixel unit U including multiple unit pixels P adjacent to each other (for example, two unit pixels P adjacent to each other in a row direction or a column direction, or four unit pixels P arranged in two rows and two columns), and one microlens (one microlens 203L) is disposed to extend over the multiple unit pixels included in this pixel unit U (for example, see FIGS. 5 and 6). In the present embodiment, a plurality of scatterers 301, 302, 303, . . . having different refractive indices is stacked in a collection optical path of the microlens 203L.

The image-plane phase-difference pixel P₀ includes a photoelectric converter 102 that is formed for each unit pixel P to be embedded in a semiconductor substrate 101 having a first surface 101S1 and a second surface 101S2 opposed to each other. In the semiconductor substrate 101, a separation section 103 is further formed between the photoelectric converters 102 adjacent to each other. An intermediate layer 201, a color filter layer 202, and the microlens 203L are stacked in this order on the first surface 101S1 serving as a light-receiving surface of the semiconductor substrate 101. In the image-plane phase-difference pixel P₀, the photoelectric converters 102 each receive light L, and photoelectrically convert the light L. The light L has been collected by the microlens 203L and separated by the color filter layer 202, and eventually includes a scattered component by the separation section 103. At this time, it is assumed that light collection onto the light-receiving surface (the first surface 101S1) has a certain degree of extent due to a diffraction limit. The plurality of scatterers 301, 302, and 303 having different refractive indices is provided in the collection optical path of the microlens 203L, specifically on or above the separation section 103 that separates the adjacent photoelectric converters 102 from each other. This causes the light L collected by the microlens 203L is received by each of the photoelectric converters 102 of the multiple unit pixels P included in the image-plane phase-difference pixel P₀ in a state in which collected light intensity is distributed stepwise by the scatterers 301, 302, and 303.

The plurality of scatterers (the scatterers 301, 302, and 303) is configured as follows, for example.

The scatterer 301 corresponds to a specific example of a “first scatterer” of the present disclosure. The scatterer 301 is provided to correct deviation in sensitivity, caused by, for example, a matching error, between the adjacent unit pixels P sharing the microlens 203L, and a part or the entirety of the scatterer 301 is embedded in the semiconductor substrate 101.

The scatterer 302 corresponds to a specific example of a “second scatterer” of the present disclosure. The scatterer 302 is disposed above the scatterer 301, that is, close to light incidence side S1 than the scatterer 301, and reduces excessive scattering by the scatterer 301.

The scatterer 301 and the scatterer 302 are configured on the basis of the following refractive index condition. It is to be noted that in order to discuss a structure having a size of a wavelength or less, an approximation of scattering intensity using a scattering cross section (Mathematical Formula (1)) of Rayleigh scattering by spherical particles is used (hereinafter referred to as a scattering intensity coefficient).

$$\begin{matrix}[ Math . 1 ] & \\ Scattering cross section α ∝ ( \frac{{( {n}_{A} / {n}_{B} )}^{2} - 1}{{( {n}_{A} / {n}_{B} )}^{2} + 2} ) & ( 1 )\end{matrix}$$

(where n_{A} is a refractive index of a scatterer, and n_{B} is a refractive index of a medium)

In a typical image-plane phase-difference pixel P₀ having a structure 1 to be described later, there is a possibility that color mixture occurs between the image-plane phase-difference pixels P₀ adjacent to each other due to excessive scattering caused by a refractive index difference between the semiconductor-substrate 101 and the separation section 103. For example, assuming that the semiconductor substrate 101 is formed using a silicon (Si) substrate and the separation section 103 is formed using silicon oxide (SiO), in a structure in which only the scatterer 301 is embedded in the semiconductor substrate 101, the scattering intensity coefficient thereof is 0.16. Meanwhile, as illustrated in FIG. 1, in the structure (the structure 1) in which the scatterer 302 is disposed above the scatterer 301, for example, in a case where the refractive index of the scatterer 302 is smaller than 0.56 or larger than 2.54, scattering larger than that in the structure 1 occurs. Accordingly, a material having a refractive index between the values is selected as a constituent material of the scatterer 302. In addition, in a case where the refractive index is too close to that of silicon oxide, scattering itself does not occur.

From the above, it is desirable that scattering at an interface between the scatterer 302 and the scatterer 301 be smaller than scattering at an interface between the scatterer 301 and the semiconductor substrate 101. That is, it is desirable to select a material that allows for α₁₂<α₀₁, where the refractive index of the semiconductor substrate 101 is N₀, the refractive index of the scatterer 301 embedded in the semiconductor substrate 101 is N₁, the refractive index of the scatterer 302 disposed above the scatterer 301 is N₂, and the above mathematical formula (1) is used to determine α₁₂ as scattering at the interface between the scatterer 302 (N₂) and the scatterer 301 (N₁) and α₀₁ as the scattering at the interface between the scatterer 301 (N₁) and the semiconductor substrate 101 (N₀). Thus, in the image-plane phase-difference pixel P₀ according to the present embodiment, the light L collected by the microlens 203L is scattered to some extent by the scatterer 302; therefore, excessive scattering by the scatterer 301 embedded in the semiconductor-substrate 101 is reduced, and occurrence of color mixture between the image-plane phase-difference pixels P₀ adjacent to each other is reduced.

As described above, as the constituent material of the scatterer 302 that allows a ratio (N₁/N₂) between the refractive index N₁ of the scatterer 301 and the refractive index N₂ of the scatterer 302 to be closer to 1 than a ratio (N₁/N₀) between the refractive index N₁ of the semiconductor-substrate 101 and the refractive index N₁ of the scatterer 301, the following is exemplified. Examples of the constituent material of the scatterer 302 include an intermediate refractive index material such as lanthanum fluoride (LaF₃), trifluoromethanide (CF₃), aluminum oxide (Al₂O₃), magnesium oxide (MgO), or yttrium oxide (Y₂O₃). Other examples of the constituent material of the scatterer 302 include a porous material such as a porous silicon oxide film formed by a spin coating method in which an air gap (Air) or a refractive index is controlled, fluorine-doped glass (FSG) in which SiO is doped with F or C, or SiOC (carbon-doped glass).

It is to be noted that the above-described calculation is an approximate value by a simple model, and “moderate scattering” varies depending on a peripheral structure such as a pixel pitch or a trench size constituting the separation section 103. An optimum refractive index also varies accordingly.

The scatterer 303 disposed above the scatterer 302 reduces excessive scattering by the scatterer 301, as with the scatterer 302. As illustrated in FIG. 1, multiple scatterers (the scatterers 302 and 303) are disposed above the scatterer 301, which is formed to be embedded in the semiconductor substrate 101, in a stacking direction (a Z-axis direction), which causes the light L collected by the microlens 203L to be scattered stepwise by an interface between the scatterer 303 and the scatterer 302 and the interface between the scatterer 302 and the scatterer 301. As a result, excessive scattering by the scatterer 301 embedded in the semiconductor substrate 101 is further reduced, and occurrence of color mixture between the image-plane phase-difference pixels P₀ adjacent to each other is further reduced.

### [Schematic Configuration of Photodetector]

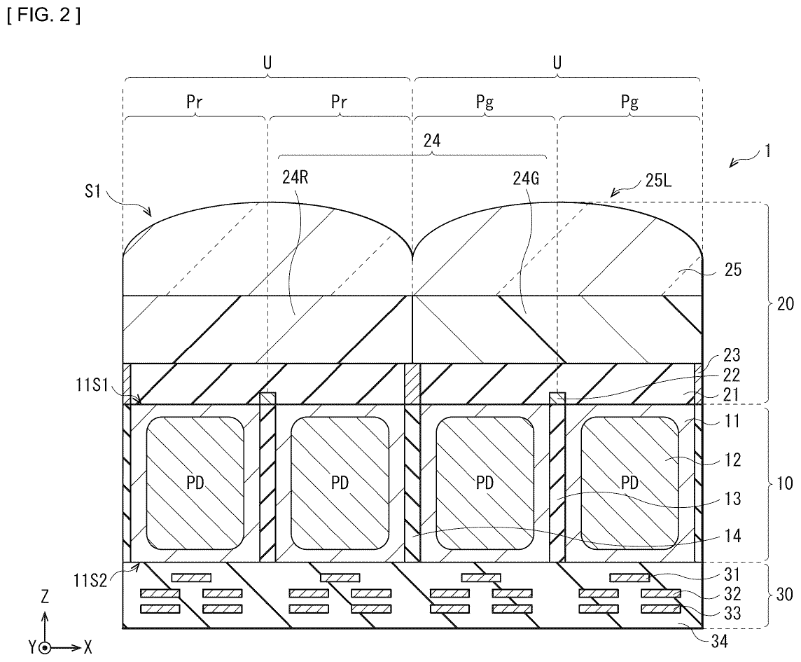

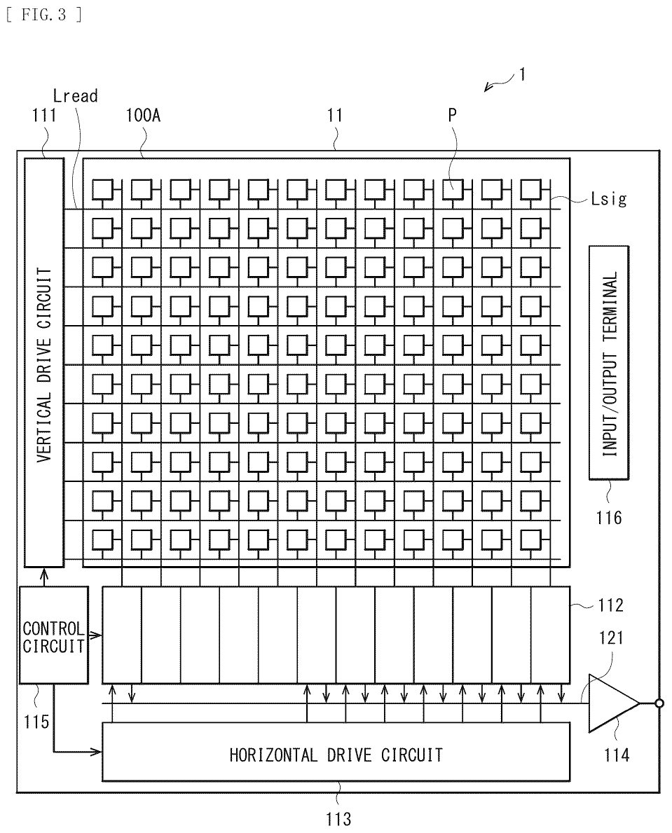

FIG. 2 schematically illustrates an example of a cross-sectional configuration of a photodetector (a photodetector 1) according to an embodiment of the present disclosure. FIG. 3 illustrates an example of an overall configuration of the photodetector 1 illustrated in FIG. 2. The photodetector 1 is, for example, a CMOS (Complementary Metal Oxide Semiconductor) image sensor or the like to be used for an electronic apparatus such as a digital still camera or a video camera, and includes, as an imaging area, a pixel section (a pixel section 100A) including a plurality of pixels (unit pixels P) two-dimensionally arranged in a matrix. The photodetector 1 is, for example, what is called a back-illuminated photodetector in the CMOS image sensor or the like.

The photodetector 1 takes in incident light (image light) from a subject through an optical lens system (not illustrated), and converts a light amount of the incident light formed as an image on an imaging plane into electric signals in units of pixels P to output the electric signals as pixel signals. The photodetector 1 includes the pixel section 100A as the imaging area on a semiconductor substrate 11. In addition, the photodetector 1 includes, for example, a vertical drive circuit 111, a column signal processing circuit 112, a horizontal drive circuit 113, an output circuit 114, a control circuit 115, and an input/output terminal 116 in a peripheral region of the pixel section 100A.

The pixel section 100A includes, for example, a plurality of unit pixels P two-dimensionally arranged in a matrix. The plurality of unit pixels P each serves as an imaging pixel and an image-plane phase-difference pixel. The imaging pixel photoelectrically converts, in the photodiode PD, a subject image formed as an image by an imaging lens, to generate a signal for image generation. The image-plane phase-difference pixel divides a pupil region of the imaging lens, and photoelectrically converts a subject image from the divided pupil region, to generate a signal for phase-difference detection.

For example, the unit pixels P are wired to a pixel drive line Lread (specifically, a row selection line and a reset control line) for each pixel row, and are wired to a vertical signal line Lsig for each pixel column. The pixel drive line Lread transmits a drive signal for signal reading from a pixel. The pixel drive line Lread has one end coupled to an output end corresponding to each row of the vertical drive circuit 111.

The vertical drive circuit 111 is a pixel driving section that includes a shift register, an address decoder, and the like and drives the unit pixels P in the pixel section 100A in row units, for example. A signal outputted from each of the unit pixels P in a pixel row selectively scanned by the vertical drive circuit 111 is supplied to the column signal processing circuit 112 through a corresponding one of the vertical signal lines Lsig. The column signal processing circuit 112 includes an amplifier, a horizontal selection switch, and the like provided for each of the vertical signal lines Lsig.

The horizontal drive circuit 113 includes a shift register, an address decoder, and the like, and drives respective horizontal selection switches of the column signal processing circuits 112 in order while scanning the horizontal selection switches. Through such selective scanning performed by the horizontal drive circuit 113, the signals of respective pixels transmitted through respective vertical signal lines Lsig are outputted in order to a horizontal signal line 121, and the signals are transmitted to outside of the semiconductor substrate 11 through the horizontal signal line 121.

The output circuit 114 performs signal processing on the signals supplied in order from the respective column signal processing circuits 112 through the horizontal signal line 121, and outputs the processed signals. The output circuit 114 performs, for example, only buffering in some cases, and performs black level adjustment, column variation correction, various types of digital signal processing, and the like in other cases.

A circuit portion including the vertical drive circuit 111, the column signal processing circuit 112, the horizontal drive circuit 113, the horizontal signal line 121, and the output circuit 114 may be formed directly on the semiconductor substrate 11, or may be provided on an external control IC. Alternatively, the circuit portion may be formed on another substrate coupled by a cable or the like.

The control circuit 115 receives a clock given from the outside of the semiconductor substrate 11, or data or the like that gives an instruction as to an operation mode, and also outputs data such as internal information about the photodetector 1. The control circuit 115 further includes a timing generator that generates various timing signals, and controls driving of peripheral circuits such as the vertical drive circuit 111, the column signal processing circuit 112, and the horizontal drive circuit 113, on the basis of the various timing signals generated by the timing generator.

The input/output terminal 116 exchanges signals with the outside.

### [Circuit Configuration of Image-Plane Phase-Difference Pixel]

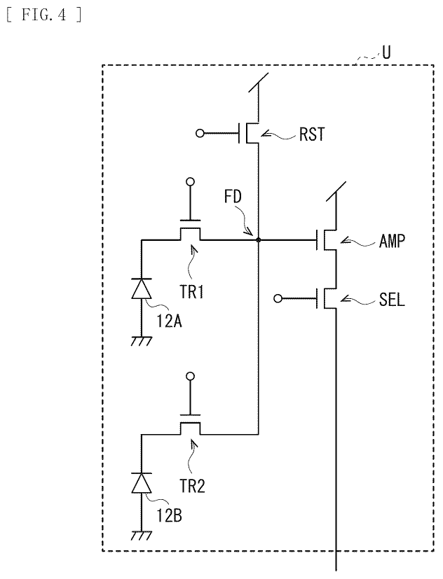

FIG. 4 illustrates an example of a readout circuit of the pixel unit U including multiple unit pixels P adjacent to each other. The pixel unit U constitutes the image-plane phase-difference pixel P₀ in the photodetector 1 illustrated in FIG. 2. It is to be noted that, in FIG. 4, the pixel unit U including two unit pixels P adjacent to each other in the row direction or the column direction is described (for example, see FIG. 5). For example, as illustrated in FIG. 4, the pixel unit U includes 12A and 12B provided for the respective two unit pixels P, transfer transistors TR1 and TR2, a floating diffusion FD provided for each pixel unit U, a reset transistor RST, an amplification transistor AMP, and a selection transistor SEL.

Each of the photoelectric converters 12A and 12B includes a photodiode (PD). The photoelectric converter 12A has an anode coupled to a ground voltage line, and a cathode coupled to a source of the transfer transistor TR1. As with the photoelectric converter 12A, the photoelectric converter 12B has an anode coupled to the ground voltage line, and a cathode coupled to a source of the transfer transistor TR2.

The transfer transistor TR1 is coupled between the photoelectric converter 12A and the floating diffusion FD. The transfer transistor TR2 is coupled between the photoelectric converter 12B and the floating diffusion FD. A drive signal TRsig is applied to each of gate electrodes of the transfer transistors TR1 and TR2. In a case where this drive signal TRsig is turned to an active state, a transfer gate of each of the transfer transistors TR1 and TR2 is turned to an electrically conductive state, and signal electric charges accumulated in the photoelectric converters 12A and 12B are transferred to the floating diffusion FD respectively through the transfer transistors TR1 and TR2.

The floating diffusion FD is coupled between each of the transfer transistors TR1 and TR2, and the amplification transistor AMP. The floating diffusion FD converts the signal electric charges transferred by the transfer transistors TR1 and TR2 into voltage signals through electric charge-voltage conversion, and outputs the voltage signals to the amplification transistor AMP.

The reset transistor RST is coupled between the floating diffusion FD and a power supply section. A drive signal RSTsig is applied to a gate electrode of the reset transistor RST. In a case where the drive signal RSTsig is turned to the active state, a reset gate of the reset transistor RST is turned to the electrically conductive state, and a potential of the floating diffusion FD is reset to a level of the power supply section.

The amplification transistor AMP has a gate electrode coupled to the floating diffusion FD, and a drain electrode coupled to the power supply section, and serves as an input section of a readout circuit for a voltage signal held by the floating diffusion FD, that is, what is called a source follower circuit. In other words, the amplification transistor AMP has a source electrode coupled to the vertical signal line Lsig through the selection transistor SEL, thereby configuring a source follower circuit with a constant current source coupled to one end of the vertical signal line Lsig.

The selection transistor SEL is coupled between the source electrode of the amplification transistor AMP and the vertical signal line Lsig. A drive signal SELsig is applied to a gate electrode of the selection transistor SEL. In a case where the drive signal SELsig is turned to the active state, the selection transistor SEL is turned to the electrically conductive state to turn the image-plane phase-difference pixel P₀ to a selected state. Accordingly, a readout signal (a pixel signal) outputted from the amplification transistor AMP is outputted to the vertical signal line Lsig through the selection transistor SEL.

In the image-plane phase-difference pixel P₀, a signal electric charge generated in the photoelectric converter 12A and a signal electric charge generated in the photoelectric converter 12B are each read, for example. The signal electric charges read from the photoelectric converter 12A and the photoelectric converter 12B are outputted, for example, to a phase-difference computation block of an external signal processor. This makes it possible to obtain a signal for phase-difference autofocusing. In addition, the signal electric charges read from the photoelectric converter 12A and the photoelectric converter 12B are added together in the floating diffusion FD, and are outputted, for example, to an imaging block of an external signal processor. This makes it possible to obtain a pixel signal based on a total electric charge of the photoelectric converter 12A and the photoelectric converter 12B.

### [Cross-Sectional Configuration of Photodetector]

FIG. 5 schematically illustrates an example of a planar configuration of the unit pixel P. FIG. 6 schematically illustrates another example of the planar configuration of the unit pixel P. The photodetector 1 is, for example, a back-illuminated photodetector as described above, and the unit pixels P two-dimensionally arranged in a matrix in the pixel section 100A each have, for example, a configuration in which a light-receiving section 10, a light-collecting section 20, and a multilayer wiring layer 30 are stacked. The light-collecting section 20 is provided on the light incident side S1 of the light-receiving section 10. The multilayer wiring layer 30 is provided on side opposite to the light incident side S1 of the light-receiving section 10.

The light-receiving section 10 includes the semiconductor substrate 11 and a plurality of photoelectric converters 12. The semiconductor substrate 11 has a first surface 11S1 and a second surface 11S2 opposed to each other. The plurality of photoelectric converters 12 is formed to be embedded in the semiconductor substrate 11. The semiconductor substrate 11 corresponds to the semiconductor substrate 101 described above, and includes, for example, a Si substrate. The photoelectric converter 12 corresponds to the photoelectric converter 102 described above. The photoelectric converter 12 includes, for example, a PIN (Positive Intrinsic Negative) type photodiode (PD), and has a pn junction in a predetermined region of the semiconductor substrate 11. The photoelectric converter 12 is formed to be embedded for each of the unit pixels P, as described above.

The light-receiving section 10 further includes a first separation section 13 and a second separation section 14.

The first separation section 13 corresponds to the separation section 103 and the scatterer 301 described above, and is provided between the adjacent unit pixels P sharing a microlens 25L. Specifically, the first separation section 13 is provided between the unit pixels P1 and P2 adjacent to each other in an X-axis direction, for example, as illustrated in FIG. 5, or is provided between the unit pixels P1, P2, P3, and P4 arranged in two rows and two columns in the X-axis direction (the row direction) and a Y-axis direction (the column direction), for example, as illustrated in FIG. 6. The first separation section 13 is provided to electrically separate the adjacent photoelectric converter 12A and photoelectric converter 12B from each other and correct deviation in sensitivity between the adjacent unit pixels P sharing the microlens 25L. The first separation section 13 penetrates through the semiconductor substrate 11, for example, between the first surface 11S1 and the second surface 11S2. The first separation section 13 is formed using, for example, silicon oxide (SiO).

In addition to an FTI (Full Trench Isolation) structure that penetrates through the semiconductor substrate 11 illustrated in FIG. 2 between the first surface 11S1 and the second surface 11S2, the first separation section 13 may have, for example, an STI (Shallow Trench Isolation) structure in which an opening (a trench) is formed in the semiconductor substrate 11 from side of the first surface 11S1 and the trench is filled with silicon oxide.

The second separation section 14 corresponds to a specific example of a “second separation section” of the present disclosure, and is provided between the adjacent pixel units U. In other words, the second separation section 14 is provided around the pixel units U, and is provided, for example, in a lattice form in the pixel section 100A. The second separation section 14 is provided to electrically separate the adjacent pixel units U from each other, and extends, for example, from side of the first surface 11S1 to side of the second surface 11S2 of the semiconductor substrate 11. The second separation section 14 is formed using, for example, silicon oxide, as with the first separation section 13.

In addition to the FTI structure that penetrates through the semiconductor substrate 11 illustrated in FIG. 2 between the first surface 11S1 and the second surface 11S2, the second separation section 14 may have, for example, an STI structure in which an opening is formed in the semiconductor substrate 11 from side of the first surface 1151 and the trench is filled with silicon oxide. In other words, the adjacent unit pixels P may be coupled to each other by the semiconductor substrate 11 on side of the second surface 11S2 of the semiconductor substrate 11.

The light-collecting section 20 is provided on the light incident side S1 of the light-receiving section 10, and includes, for example, a protection layer 21, a scattering film 22, a light-shielding film 23, a color filter layer 24, and a microlens layer 25 that are stacked in this order from side of the light-receiving section 10. The protection layer 21 covers the first surface 11S1 of the semiconductor substrate 11.

The protection layer 21 corresponds to the “intermediate layer 201” described above, and protects the first surface 11S1 of the semiconductor substrate 11 and planarizes the surface. The protection layer 21 is formed using, for example, silicon oxide, silicon nitride (SiN), silicon oxynitride (SiON), or the like.

The scattering film 22 corresponds to the “scatterer 302” described above, and is provided to reduce excessive scattering by the first separation section 13. The scattering film 22 is formed on the first separation section 13 in a layout similar to that of the first separation section 13 in plan view. Specifically, the scattering film 22 is provided between the unit pixels P1 and P2 adjacent to each other in the X-axis direction in plan view, for example, as illustrated in FIG. 5, or is provided between the unit pixels P1, P2, P3, and P4 arranged in two rows and two columns in the X-axis direction (the row direction) and the Y-axis direction (the column direction) in plan view, for example, as illustrated in FIG. 6.

It is possible to form the scattering film 22 using a constituent material that allows a ratio (N₂₂/N₁₃) between a refractive index (N₂₂) of the scattering film 22 and a refractive index (N₁₃) of the first separation section 13 to be closer to 1 than a ratio (N₁₃/N₁₁) between the refractive index (N₁₃) of the first separation section 13 and a refractive index (N₁₁) of the semiconductor-substrate 11. Examples of such a constituent material include an intermediate refractive index material such as lanthanum fluoride, trifluoromethanide, aluminum oxide, magnesium oxide, or yttrium oxide. Other examples of the constituent material of the scatterer 302 include a porous material such as a porous silicon oxide film formed by a spin coating method in which an air gap (Air) or a refractive index is controlled, fluorine-doped glass (FSG) in which SiO is doped with F or C, or SiOC (carbon-doped glass).

The light-shielding film 23 is provided to prevent leakage of light obliquely incident on the color filter layer 24 to the adjacent pixel units U that detect light of different wavelengths. The light-shielding film 23 is provided on the second separation section 14, and is formed in a layout similar to that of the second separation section 14 in plan view as illustrated in FIGS. 5 and 6. The light-shielding film 23 is provided to penetrate through the protection layer 21 in the Y-axis direction so as to optically separate the pixel units U, which detect light of different wavelengths in the protection layer 21, from each other. In addition, a part of the light-shielding film 23 may be embedded in the second separation section 14. This allows the second separation section 14 to electrically and optically separate the adjacent pixel units U from each other.

Examples of a constituent material of the light-shielding film 23 include a material having a light-shielding property. Specific examples of the constituent material of the light-shielding film 23 include tungsten (W), silver (Ag), copper (Cu), titanium (Ti), aluminum (Al), and alloys thereof. Other examples of the constituent material of the light-shielding film 23 include a metal compound such as TiN. The light-shielding film 23 may be formed, for example, as a single-layer film or a stacked film.

The color filter layer 24 allows light of a predetermined wavelength to selectively pass therethrough. As illustrated in FIG. 2, the color filter layer 24 includes, for example, a red color filter layer 24R, a green color filter layer 24G, and an unillustrated blue color filter layer 24B. The red color filter layer 24R allows red light (R) to selectively pass therethrough. The green color filter layer 24G allows green light (G) to selectively pass therethrough. The blue color filter layer 24G allows blue light (B) to selectively pass therethrough. In addition, the color filter layer 24 may include filters that each allow a corresponding one of cyan, magenta, and yellow to selectively pass therethrough. The color filter layers 24R, 24G, and 24B of respective colors are provided for the respective pixel units U, and in the unit pixels P (a red pixel Pr, a green pixel Pg, and a blue pixel Pb) provided with the color filter layers 24R, 24G, and 24B of the respective colors, for example, each of the photoelectric converters 12 detects light of a corresponding color. It is possible to form the color filter layer 24 using, for example, a pigment or a dye. A film thickness of the color filter layer 24 may differ for each color in consideration of color reproducibility and sensor sensitivity by a spectral spectrum thereof. It is to be noted that it is possible to regard a layer including a transparent material as the color filter layer 24 in a black-and-white pixel. It is possible to regard a layer including a material that allows infrared rays to selectively pass therethrough as the color filter layer 24 in a pixel for infrared rays.

The microlens layer 25 is provided to cover the entire surface of the pixel section 100A, and includes a plurality of microlenses 25L on a front surface thereof. The microlens 25L is provided to collect, into the first surface 11S1 serving as a light-receiving surface, light entering from above, and is provided for each pixel unit U as illustrated in FIG. 2. The microlens layer 25 including the microlenses 25L is formed using, for example, a high refractive index material. Specifically, the microlens layer 25 is formed using, for example, an inorganic material such as silicon oxide or silicon nitride. In addition, the microlens layer 25 may be formed using an organic material having a high refractive index such as episulfide-based resin, a thietane compound, or resin thereof. The microlens 25L is not particularly limited in shape, and it is possible to employ any of various lens shapes such as a half-sphere shape or a half-tubular shape.

The multilayer wiring layer 30 is provided on side opposite to the light incident side S1 of the light-receiving section 10. The multilayer wiring layer 30 has a configuration in which a plurality of wiring layers 31, 32, and 33 is stacked with an interlayer insulating layer 34 interposed therebetween. In addition to the readout circuit described above, the vertical drive circuit 111, the column signal processing circuit 112, the horizontal drive circuit 113, the output circuit 114, the control circuit 115, the input/output terminal 116, and the like are formed on the multilayer wiring layer 30, for example.

The wiring layers 31, 32, and 33 are formed using, for example, aluminum (Al), copper (Cu), tungsten (W), or the like. In addition, the wiring layers 31, 32, and 33 may be formed using polysilicon (Poly-Si).

For example, the interlayer insulating layer 34 includes a single-layer film including one of silicon oxide, TEOS, silicon nitride, silicon oxynitride, and the like, or includes a stacked film including two or more thereof.

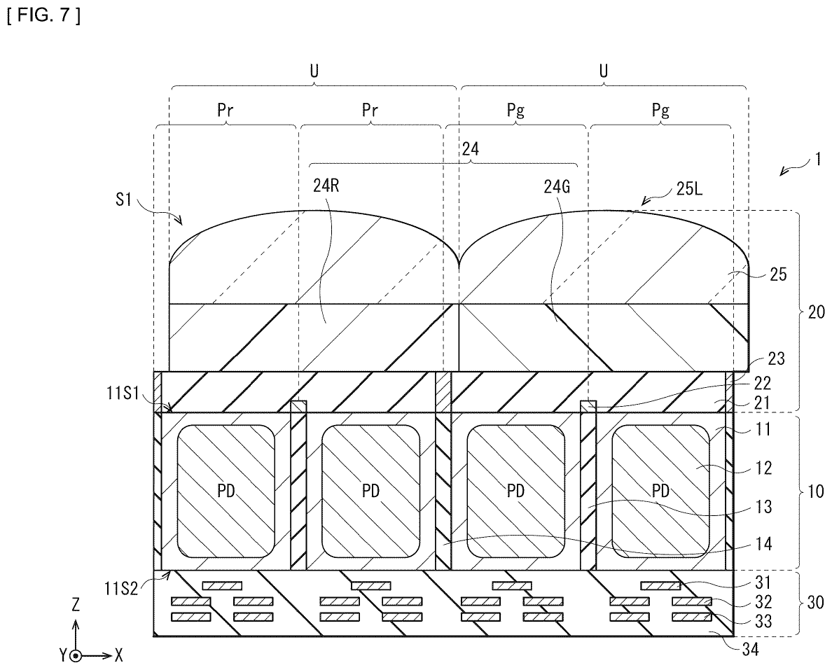

It is to be noted that the color filter layer 24 and the microlens 25L provided for each pixel unit U may be shifted toward an optical center of the pixel section 100A in accordance with a position in the pixel section 100A, for example, as illustrated in FIG. 7. Shift amounts of the color filter layer 24 and the microlens 25L differ substantially concentrically from the optical center of the pixel portion 100A.

### [Method of Manufacturing Scattering Film]

It is possible to form the scattering film 22 as follows, for example.

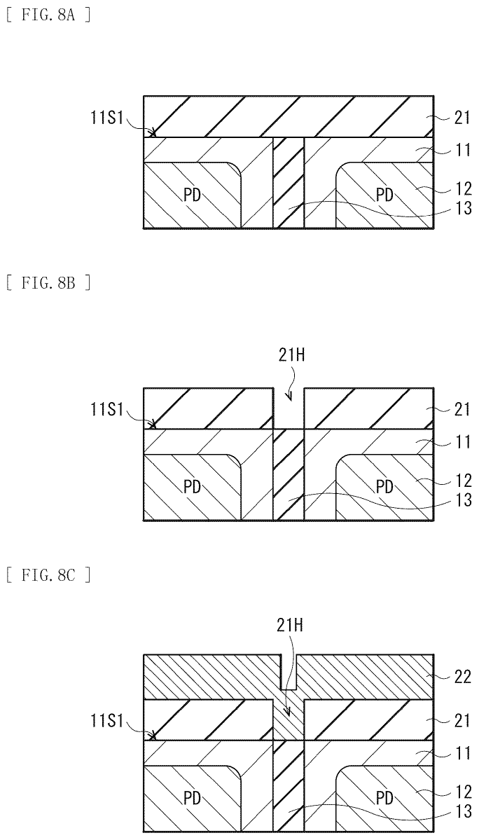

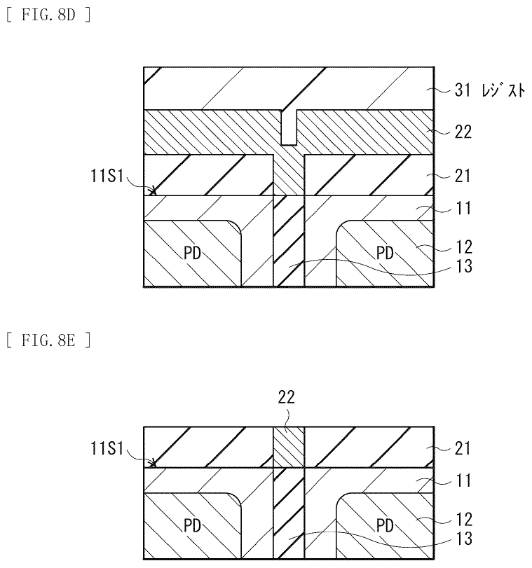

First, as illustrated in FIG. 8A, the protection layer 21 is formed on the first surface 11S1 of the semiconductor substrate 11 with use of, for example, a chemical vapor deposition (CVD) method, sputtering, an atomic layer deposition (ALD) method, or the like. Next, as illustrated in FIG. 8B, the protection layer 21 is etched by a lithography technique to form an opening 21H on the first separation section 13.

Thereafter, as illustrated in FIG. 8C, the scattering film 22 is formed on the protection layer 21 with use of, for example, a CVD method or an ALD method so as to be embedded in the opening 21H. Next, as illustrated in FIG. 8D, a resist 41 is formed on the scattering film 22 to planarize a surface. Thereafter, as illustrated in FIG. 8E, the scattering film 22 is etched back together with the resist 41. Thus, the scattering film 22 is selectively formed on the first separation section 13.

It is possible to form the scattering film 22 as follows, for example.

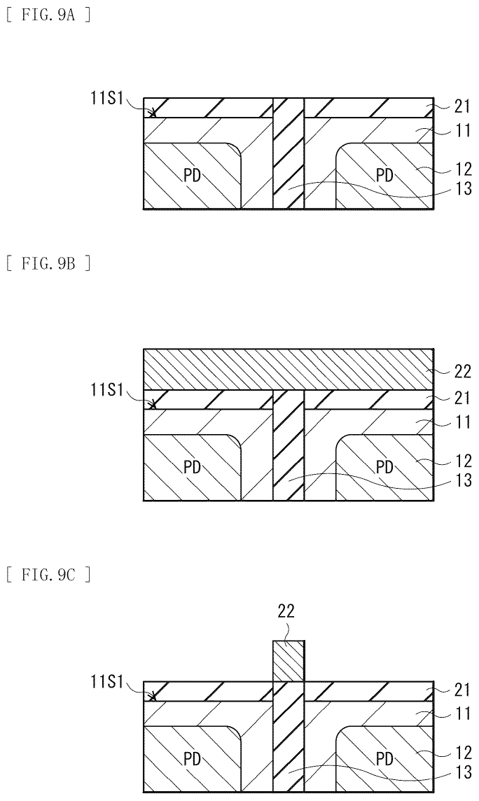

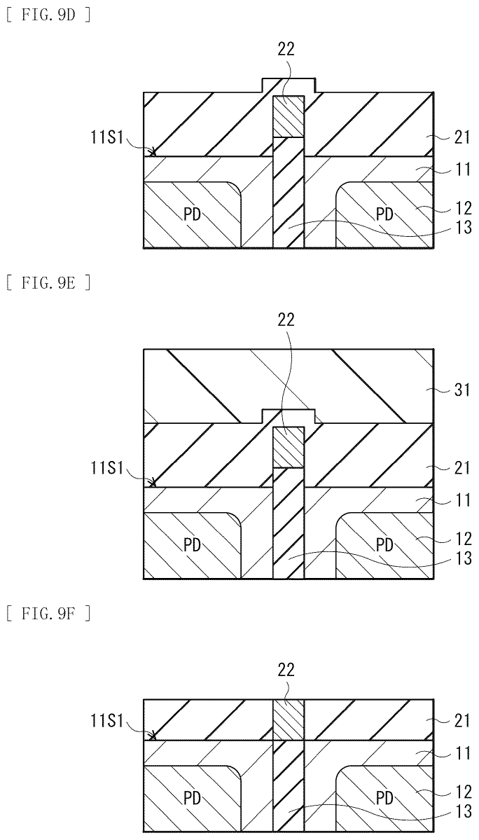

First, as illustrated in FIG. 9A, the protection layer 21 is thinly formed on the first surface 11S1 of the semiconductor substrate 11, from which the first separation section 13 is projected on side of the first surface 11S1 of the semiconductor substrate 11, with use of, for example, a CVD method, sputtering, an ALD method, or the like so as to fill in the surroundings of the first separation section 13. Thereafter, as illustrated in FIG. 9B, the scattering film 22 is formed with use of, for example, a CVD method, sputtering, an ALD method, or the like.

Next, as illustrated in FIG. 9C, the scattering film 22 is etched by, for example, a lithography technique to selectively pattern the scattering film 22 on the first separation section 13. Thereafter, as illustrated in FIG. 9D, the protection layer 21 is formed with use of, for example, a CVD method, sputtering, an ALD method, or the like to embed the scattering film 22. Next, as illustrated in FIG. 9E, the resist 41 is formed to embed projections and recesses formed on a surface of the protection layer 21. Thereafter, as illustrated in FIG. 9F, the protection layer 21 is etched back together with the resist 41 to planarize the surface.

### Workings and Effects

In the photodetector 1 according to the present embodiment, the microlens 25L that extends over the multiple unit pixels P adjacent to each other is disposed on side of the light-receiving surface (the first surface 11S1) of the semiconductor substrate 11 including the photoelectric converter 12 for each unit pixel P, and scatterers (the first separation section 13 and the scattering film 22) having different refractive indices are stacked in a collection optical path of the microlens 25L. This suppresses strong scattering of incident light by the first separation section 13. This is described below.

In recent years, a semiconductor imaging device (a photodetector) having a focus detection function by a phase-difference detection method has become popular. The photodetector having the focus detection function by the phase-difference detection method has a structure that, for phase-difference detection, multiple pixels of a same color receive light with one on-chip lens (OCL). In such a photodetector, a scatterer is placed on an optical path to thereby scatter collected light and reduce a sensitivity difference, thus correcting deviation in light reception sensitivity caused by a manufacturing error between a phase-difference detection pixel pair.

In a commercialized actual structure, a pixel separation trench is disposed at a light-collected point, and a scatterer such as SiO is embedded inside the trench, thereby achieving an effect of correcting a sensitivity difference. However, there is an issue of color mixture to adjacent pixels due to excessive scattering by this scatterer.

In contrast, in the present embodiment, the scattering film 22 having a refractive index different from that of the first separation section 13 is provided on the first separation section 13 provided in the collection optical path of the microlens 25L. The first separation section 13 separates the photoelectric converters 12 from each other. The photoelectric converters 12 are provided in the respective multiple adjacent unit pixels P sharing the microlens 25L. As a result, the light L scattered to some extent by the scattering film 22 is scattered by the first separation section 13. This suppresses strong scattering of incident light by the first separation section 13 while maintaining the effect of correcting the sensitivity difference by the first separation section 13.

As described above, in the photodetector 1 according to the present embodiment, it is possible to suppress color mixture between the image-plane phase-difference pixels P₀ adjacent to each other while correcting deviation in a sensitivity difference between the multiple unit pixels P sharing the microlens 25L.

Next, description is given of Modification Examples 1 to 14 of the present disclosure. Hereinafter, components similar to those in the embodiment described above are denoted by the same reference numerals, and description thereof is omitted as appropriate.

### 2. MODIFICATION EXAMPLES

### 2-1. Modification Example 1

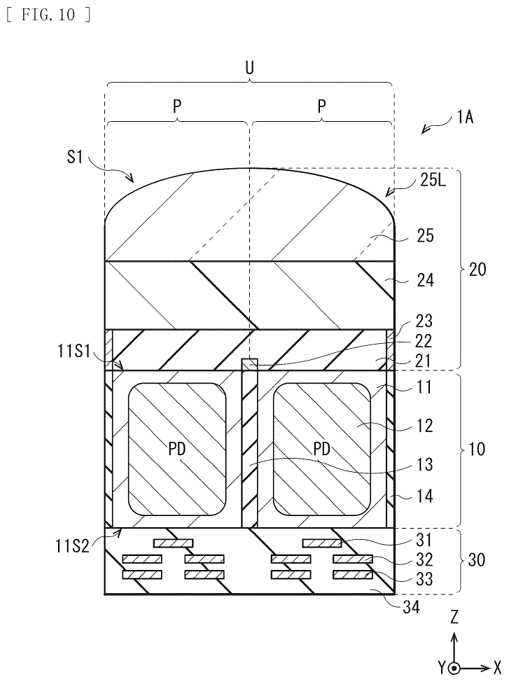

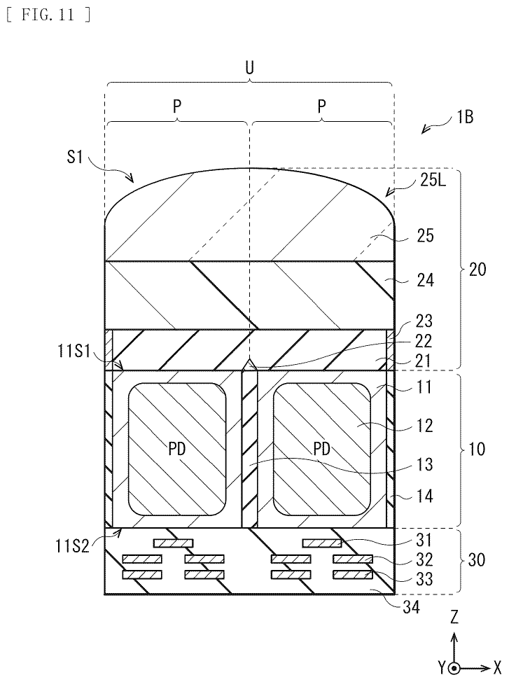

FIG. 10 schematically illustrates an example of a cross-sectional configuration of a photodetector (a photodetector 1A) according to Modification Example 1 of the present disclosure. The photodetector 1A is, for example, a CMOS image sensor or the like to be used for an electronic apparatus such as a digital still camera or a video camera, and is, for example, what is called a back-illuminated photodetector as with the embodiment described above.

It is desirable that the scattering film 22 formed on the first separation section 13 not be formed at an interface with the semiconductor substrate 11. Accordingly, the scattering film 22 is preferably formed to have a width narrower than a width of the first separation section 13 as illustrated in FIG. 10. This suppresses occurrence of strong scattering at the interface between the scattering film 22 and the semiconductor substrate 11.

### 2-2. Modification Example 2

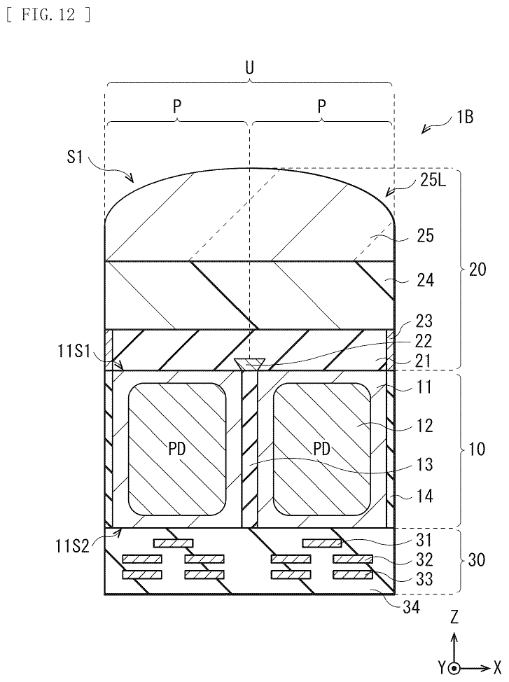

FIG. 11 schematically illustrates an example of a cross-sectional configuration of a photodetector (a photodetector 1B) according to Modification Example 2 of the present disclosure. FIG. 12 schematically illustrates another example of the cross-sectional configuration of the photodetector 1B according to Modification Example 2 of the present disclosure. The photodetector 1B is, for example, a CMOS image sensor or the like to be used for an electronic apparatus such as a digital still camera or a video camera, and is, for example, what is called a back-illuminated photodetector as with the embodiment described above.

In the embodiment described above and Modification Example 1, an example has been described in which the scattering film 22 having a rectangular shape in cross-sectional view is provided, but the shape of the scattering film 22 is not limited thereto. As illustrated in FIG. 11, the scattering film 22 may have a triangular shape having a vertex on side of the microlens 25L. Alternatively, as illustrated in FIG. 12, the scattering film 22 may have a trapezoidal shape expanding toward the microlens 25L. Changing an area of an interface between a top surface of the scattering film 22 and the protection layer 21 in such a manner makes it possible to control scattering intensity.

### 2-3. Modification Example 3

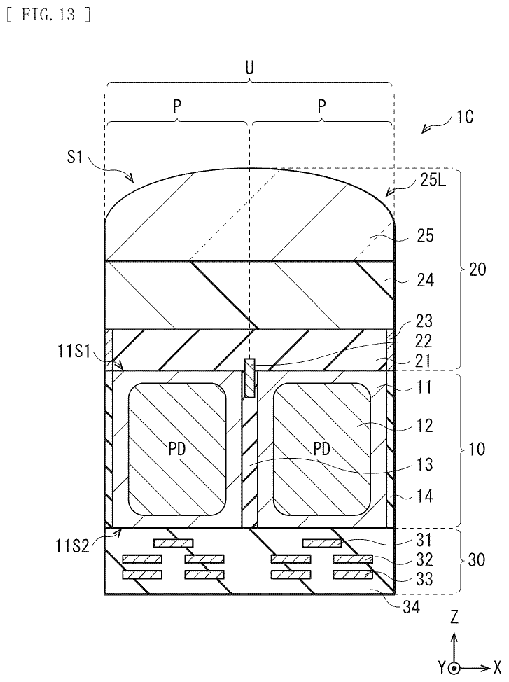

FIG. 13 schematically illustrates an example of a cross-sectional configuration of a photodetector (a photodetector 1C) according to Modification Example 3 of the present disclosure. The photodetector 1C is, for example, a CMOS image sensor or the like to be used for an electronic apparatus such as a digital still camera or a video camera, and is, for example, what is called a back-illuminated photodetector as with the embodiment described above.

In the embodiment described above and the like, an example has been described in which the scattering film 22 is formed on the first separation section 13 that forms a same surface with the first surface 11S1 of the semiconductor substrate 11, but this is not limitative. As illustrated in FIG. 13, a part of the scattering film 22 may be embedded in the first separation section 13. Increasing a surface area of the scattering film 22 in such a manner makes it possible to improve a scattering effect by the scattering film 22.

### 2-4. Modification Example 4

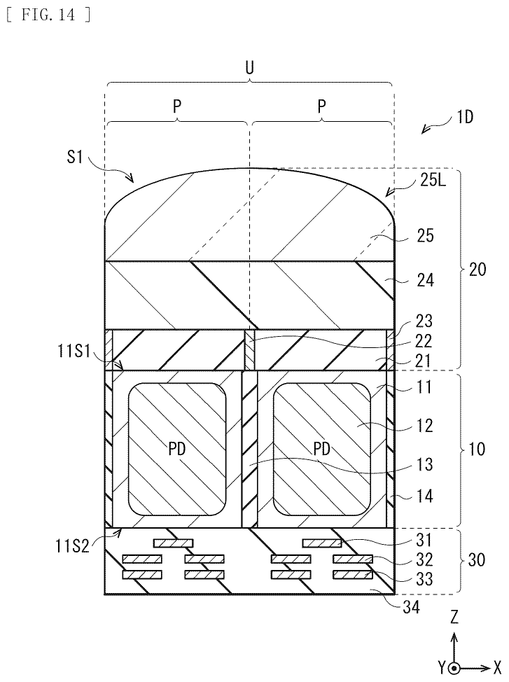

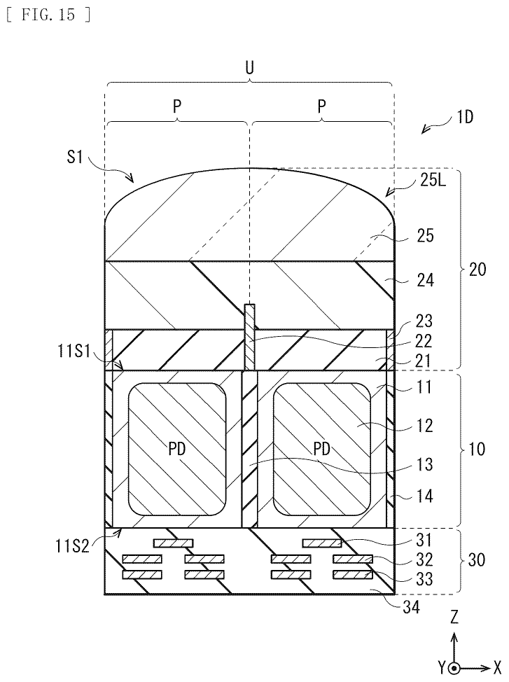

FIG. 14 schematically illustrates an example of a cross-sectional configuration of a photodetector (a photodetector 1D) according to Modification Example 4 of the present disclosure. FIG. 15 schematically illustrates another example of the cross-sectional configuration of the photodetector 1D according to Modification Example 4 of the present disclosure. The photodetector 1D is, for example, a CMOS image sensor or the like to be used for an electronic apparatus such as a digital still camera or a video camera, and is, for example, what is called a back-illuminated photodetector as with the embodiment described above.

As illustrated in FIG. 14, the scattering film 22 may penetrate through the protection layer 21 so as to separate the first surface 11S1 of the semiconductor substrate 11 and the color filter layer 24 from each other. Alternatively, as illustrated in FIG. 15, a part of the scattering film 22 may be projected into the color filter layer 24. As a result, as with Modification Example 3 described above, increasing the surface area of the scattering film 22 makes it possible to improve the scattering effect by the scattering film 22.

In addition, in a case where an interface between the scattering film 22 and the color filter layer 24 is formed, scattering occurs due to a refractive index difference between the scattering film 22 and the color filter layer 24. Depending on the refractive index of the color filter layer 24, this scattering effect makes it possible to further suppress color mixture between the image-plane phase-difference pixels P₀ adjacent to each other.

### 2-5. Modification Example 5

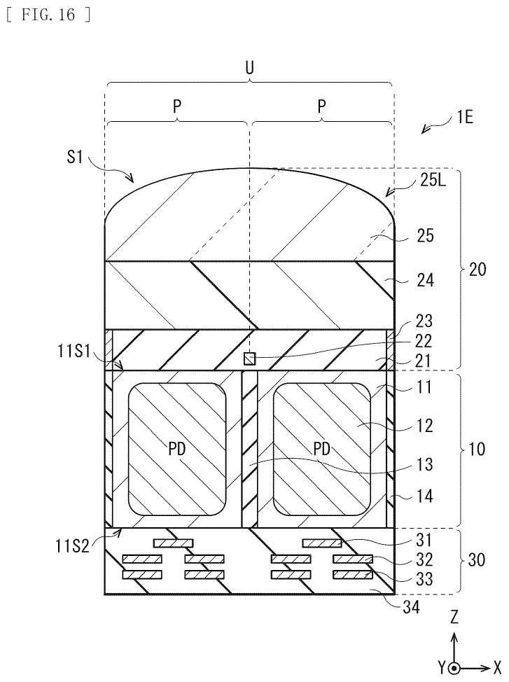

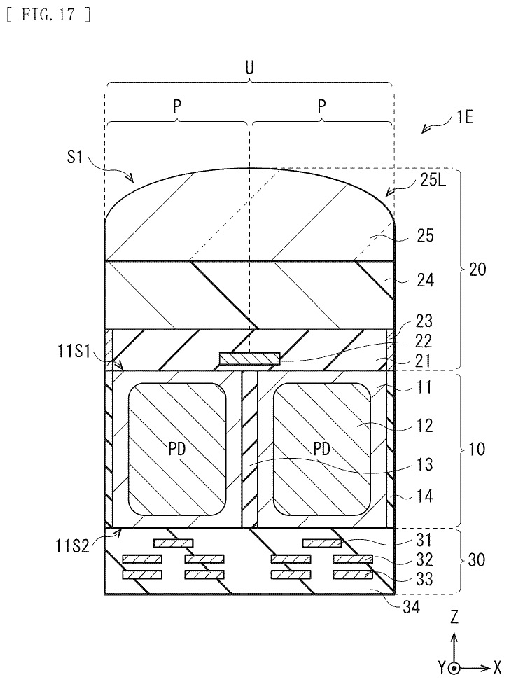

FIG. 16 schematically illustrates an example of a cross-sectional configuration of a photodetector (a photodetector 1E) according to Modification Example 5 of the present disclosure. FIG. 17 schematically illustrates another example of the cross-sectional configuration of the photodetector 1E according to Modification Example 5 of the present disclosure. The photodetector 1E is, for example, a CMOS image sensor or the like to be used for an electronic apparatus such as a digital still camera or a video camera, and is, for example, what is called a back-illuminated photodetector as with the embodiment described above.

In the embodiment described above and the like, an example has been described in which the scattering film 22 is formed on the first separation section 13 that forms the same surface with the first surface 11S1 of the semiconductor substrate 11, but this is not limitative. As illustrated in FIG. 16, the scattering film 22 may be embedded in the protection layer 21 so as to have the protection layer 21 between the first separation section 13 and the scattering film 22. In this case, there is no possibility that the scattering film 22 forms an interface with the semiconductor substrate 11; therefore, as illustrated in FIG. 17, the scattering film 22 is provided to have a width wider than that of the first separation section 13.

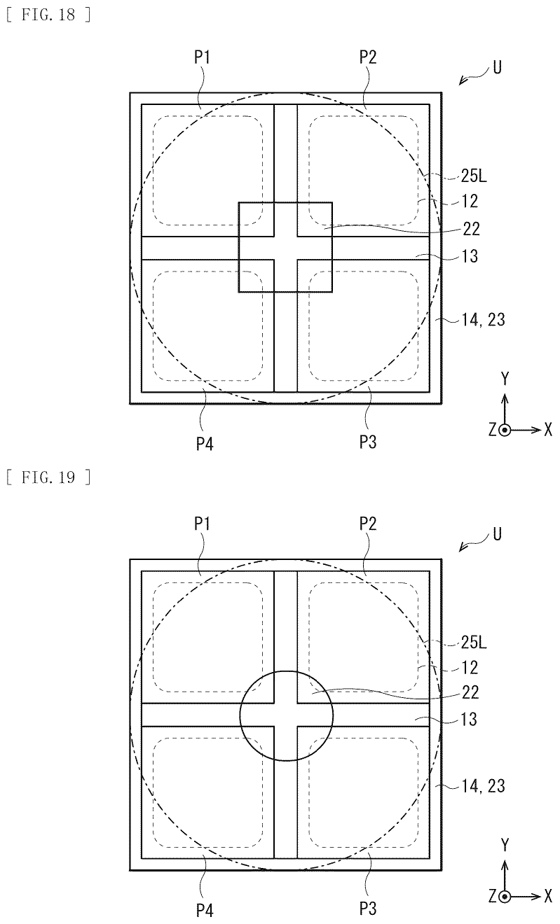

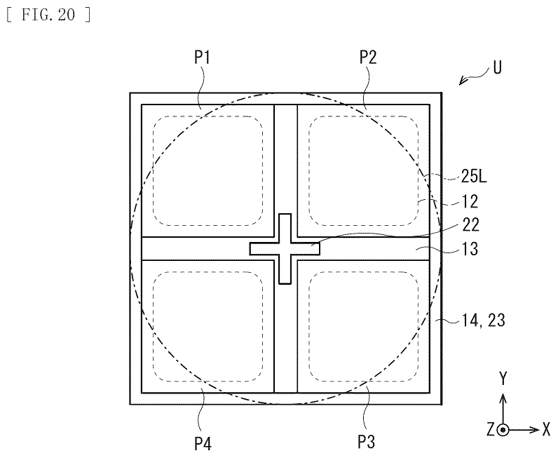

As illustrated in FIG. 17, in a case where the scattering film 22 is formed to have a width wider than that of the first separation section 13, the scattering film 22 may be partially provided in the collection optical path of the microlens 25L. A planar shape of the scattering film 22 may be a rectangular shape as illustrated in FIG. 18, or may be a circular shape as illustrated in FIG. 19. Alternatively, as illustrated in FIG. 20, the scattering film 22 may be formed above the first separation section 13, for example, in a cross shape along the shape of the first separation section 13.

### 2-6. Modification Example 6

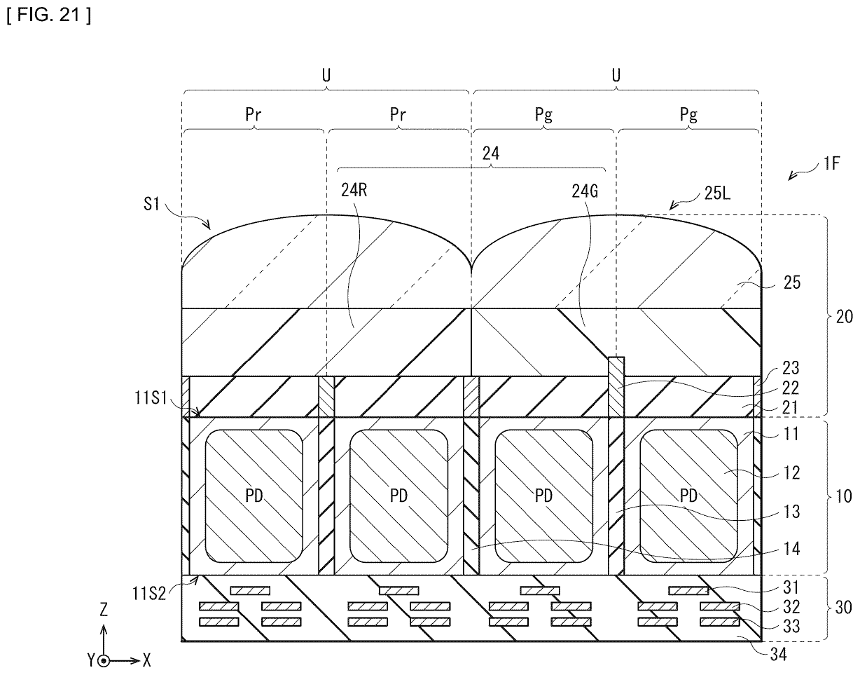

FIG. 21 schematically illustrates an example of a cross-sectional configuration of a photodetector (a photodetector 1F) according to Modification Example 6 of the present disclosure. The photodetector 1F is, for example, a CMOS image sensor or the like to be used for an electronic apparatus such as a digital still camera or a video camera, and is, for example, what is called a back-illuminated photodetector as with the embodiment described above.

As illustrated in FIG. 21, the scattering film 22 may be individually formed so as to have a height differing in accordance with spectral characteristics and refractive indices of the respective color filter layers 24R, 24G, and 24B provided for the respective pixel unit units U.

### 2-7. Modification Example 7

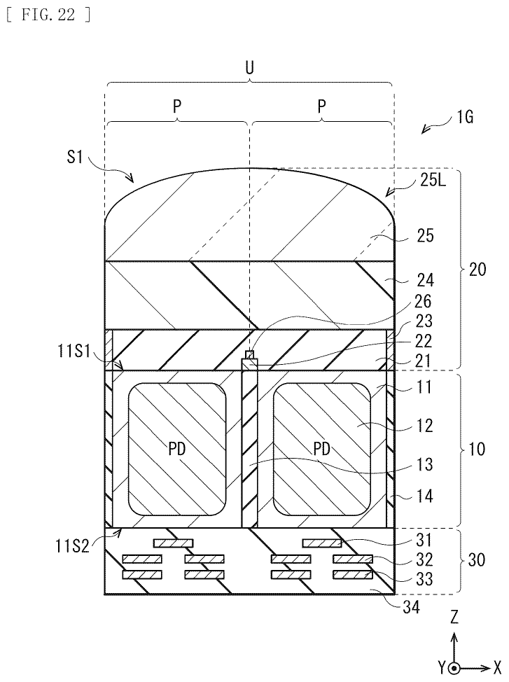

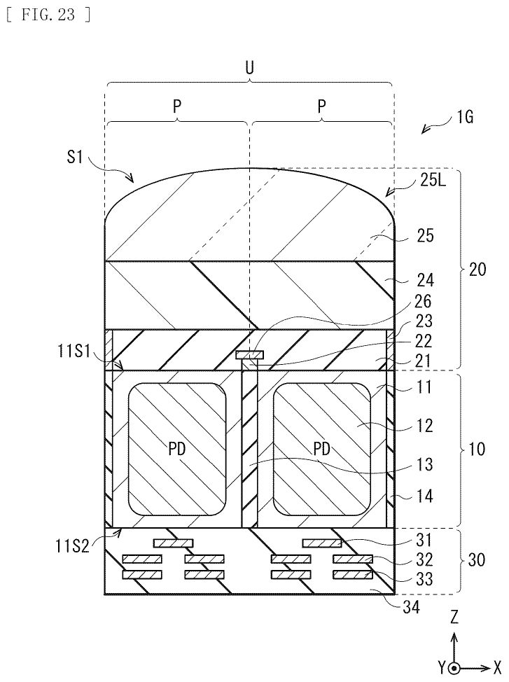

FIG. 22 schematically illustrates an example of a cross-sectional configuration of a photodetector (a photodetector 1G) according to Modification Example 7 of the present disclosure. FIG. 23 schematically illustrates another example of the cross-sectional configuration of the photodetector 1G according to Modification Example 7 of the present disclosure. The photodetector 1G is, for example, a CMOS image sensor or the like to be used for an electronic apparatus such as a digital still camera or a video camera, and is, for example, what is called a back-illuminated photodetector as with the embodiment described above.

As illustrated in FIG. 22, a plurality of scattering films 22 and 26 may be stacked on the first separation section 13. In a case where the plurality of scattering films 22 and 26 is stacked in such a manner, the scattering film 26 provided closer to the light incident side S1 may be provided to have a width narrower than that of the scattering film 22 as illustrated in FIG. 22, or may be provided to have a width wider than that of the scattering film 22 as illustrated in FIG. 23. Stacking the plurality of scattering films 22 and 26 on the first separation section 13 in such a manner makes it possible to individually form scatterers suitable for the respective semiconductor substrate 11 and color filter layer 24.

### 2-8. Modification Example 8

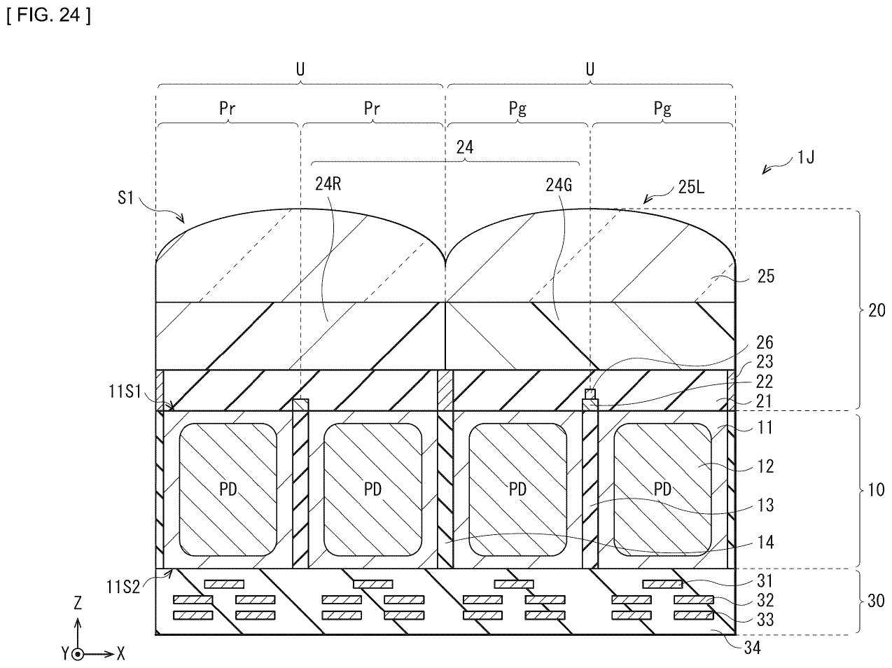

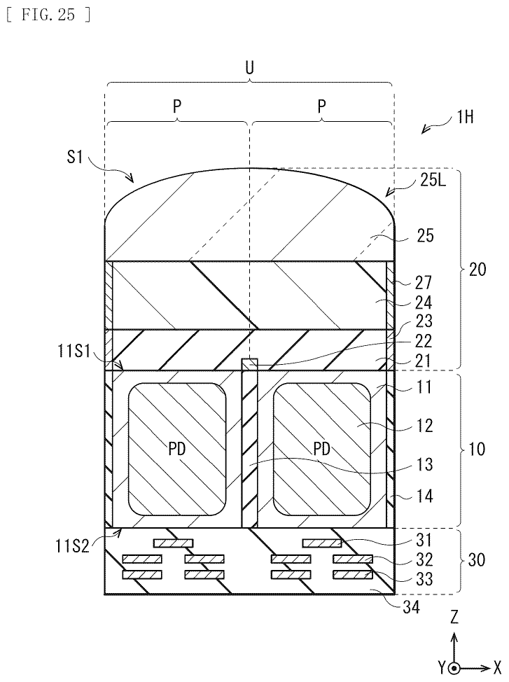

FIG. 24 schematically illustrates an example of a cross-sectional configuration of a photodetector (a photodetector 1J) according to Modification Example 8 of the present disclosure. The photodetector 1J is, for example, a CMOS image sensor or the like to be used for an electronic apparatus such as a digital still camera or a video camera, and is, for example, what is called a back-illuminated photodetector as with the embodiment described above.

As illustrated in FIG. 24, one scatterer or a plurality of scatterers (for example, the scattering films 22 and 26) may be individually formed in accordance with the spectral characteristic and the refractive index of each of the color filter layers 24R, 24G, and 24B provided for the respective pixel unit units U.

### 2-9. Modification Example 9

FIG. 25 schematically illustrates an example of a cross-sectional configuration of a photodetector (a photodetector 1H) according to Modification Example 9 of the present disclosure. The photodetector 1H is, for example, a CMOS image sensor or the like to be used for an electronic apparatus such as a digital still camera or a video camera, and is, for example, what is called a back-illuminated photodetector as with the embodiment described above.

A partition wall 27 may be provided in the color filter layer 24 between the adjacent pixel units U. The partition wall 27 separates the color filter layers 24R, 24G, and 24B from each other. This makes it possible to improve an effect of the scattering film 22 synergistically with an improvement in light-collection characteristics. Accordingly, it is possible to further suppress color mixture between the image-plane phase-difference pixels P₀ adjacent to each other.

### 2-10. Modification Example 10

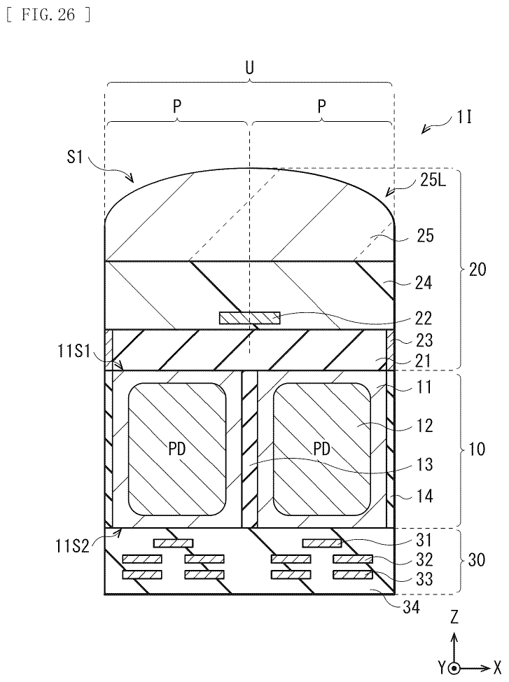

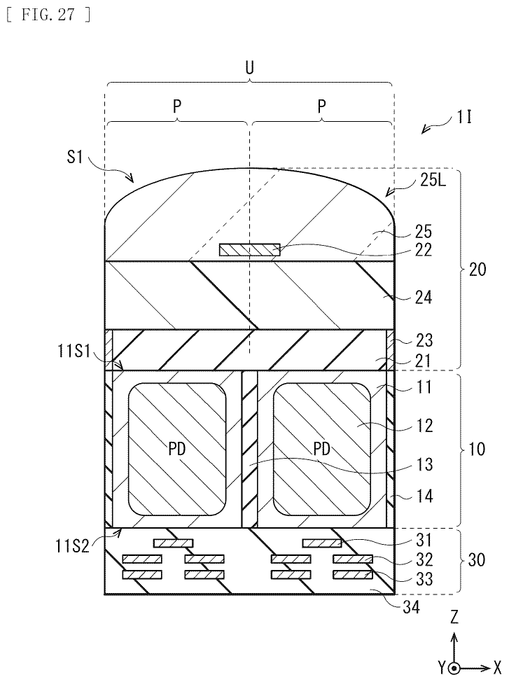

FIG. 26 schematically illustrates an example of a cross-sectional configuration of a photodetector (a photodetector 1I) according to Modification Example 10 of the present disclosure. FIG. 27 schematically illustrates another example of the cross-sectional configuration of the photodetector 1G according to Modification Example 10 of the present disclosure. The photodetector 1G is, for example, a CMOS image sensor or the like to be used for an electronic apparatus such as a digital still camera or a video camera, and is, for example, what is called a back-illuminated photodetector as with the embodiment described above.

In the embodiment described above and the like, an example has been described in which the scattering film 22 is provided in the protection layer 21, but a position where the scattering film 22 is formed is not limited thereto. The scattering film 22 may be embedded in the color filter layer 24 as illustrated in FIG. 26, or may be embedded in the microlens layer 25 as illustrated in FIG. 27. Changing a distance between the semiconductor substrate 11 and the scattering film 22 in accordance with a refractive index condition of the scattering film 22 and a condition such as a film thickness of each member or a curvature of the microlens 25L makes it possible to improve a scattering effect in the color filter layer 24 or in the microlens layer 25.

### Other Modification Examples

In the photodetectors (for example, the photodetector 1) described in the embodiment above and Modification Examples 1 to 10, the first separation section 13 and/or the second separation section 14 having any of the following configurations makes it possible to suppress color mixture due to scattering in the first separation section 13 and the second separation section 14.

### 2-11. Modification Example 11

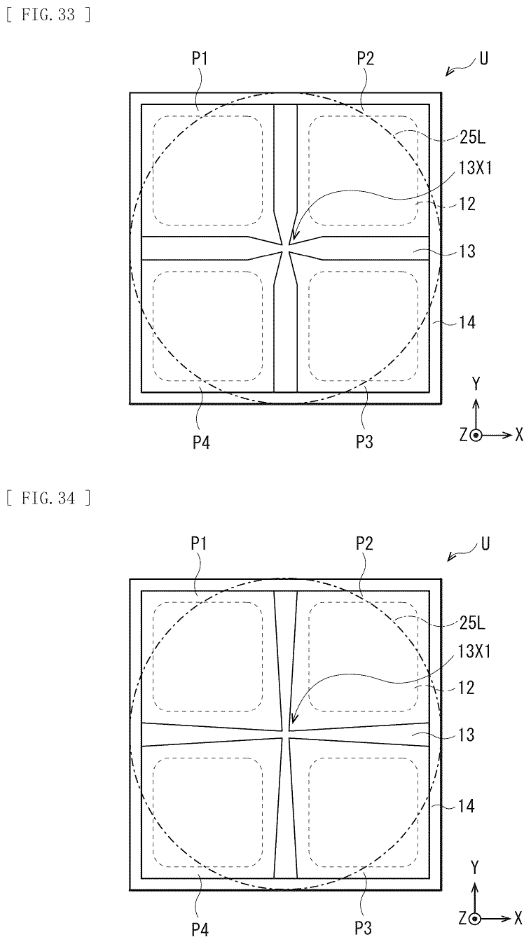

FIG. 33 schematically illustrates an example of a planar configuration of a photodetector according to Modification Example 11 of the present disclosure. FIG. 34 schematically illustrates another example of the planar configuration of the photodetector according to Modification Example 11 of the present disclosure.

The first separation section 13 that separates the adjacent unit pixels P sharing the microlens 25L from each other may have a reduced portion (for example, a reduced portion 13X1) having a line width reduced smaller than that of another portion in plan view.

Specifically, for example, as illustrated in FIG. 33, in the first separation section 13 provided between the unit pixels P1, P2, P3, and P4 arranged in two rows and two columns in the X-axis direction (the row direction) and the Y-axis direction (the column direction), the reduced portion 13X1 having a line width reduced smaller than that of another portion in plan view may be provided in the first separation section 13 in the collection optical path of the microlens 25L. In addition to partially providing a reduced portion 13X in the first separation section 13 in the collection optical path of the microlens 25L, for example, as illustrated in FIG. 34, the reduced portion 13X may be configured to have the line width gradually reduced toward the collection optical path of the microlens 25L from an intersection portion between the first separation section 13 and the second separation section.

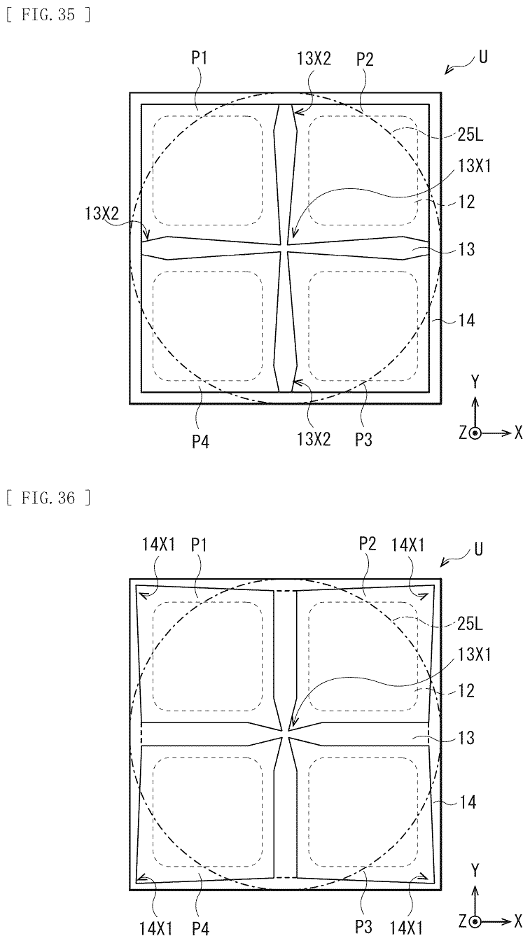

In addition, the reduced portion of the first separation section 13 may be provided at a position other than a position on the collection optical path of the microlens 25L. For example, as illustrated in FIG. 35, a reduced portion 13X2 may be further provided in the intersection portion between the first separation section 13 and the second separation section 14.

A photodetector to be used as a CMOS image sensor or the like adopts a pixel separation structure (a separation section) that obtains phase-difference information from an output difference of each pixel and uses the phase-difference information for autofocusing. In order to obtain the phase-difference information, a structure is typically adopted in which an on-chip lens (OCL) is disposed to extend over multiple unit pixels. In particular, a 2×2 OCL structure in which one OCL is disposed on four unit pixels arranged in 2 rows and 2 columns is a structure that is configured to achieve both obtainment of a phase difference and an advantage in terms of image quality such as resolution or HDR. Meanwhile, the 2×2 OCL structure includes a separation section at a light-collected point, which causes an issue that color mixture deteriorates due to optical factors by scattering.

There are two major factors in deterioration of color mixture due to optical scattering.

A first factor is a refractive index difference between a material embedded in the separation section at the light-collected point by the on-chip lens and a pixel region material. As the difference is larger, stronger scattering occurs and the deterioration of color mixture becomes more remarkable. In a photodetector for obtaining an optical signal in a visible light region, Si having a high refractive index of about 3 to about 4 is typically used as the pixel region material. At this time, it is preferable to embed a high refractive index material having a small refractive index difference from Si in the separation section. However, an embedded film here affects dark time characteristics of the photodetector, which imposes a strong material restriction.

A second factor is the size of the separation section. As a ratio of the separation section serving as a scatterer with respect to a spot size of light collected by the on-chip lens is larger, stronger scattering occurs and the deterioration of color mixture becomes more remarkable.

In contrast, in the present modification example, in the first separation section 13 that separates the adjacent unit pixels P sharing the microlens 25L from each other, the reduced portion (for example, the reduced portion 13X1) having a line width reduced smaller than that of another portion in plan view is provided for example, in the first separation section 13 in the collection optical path of the microlens 25L. As a result, a ratio of the first separation section 13 with respect to a spot size of light collected by the microlens 25L is reduced. Accordingly, it is possible to suppress color mixture in the collection optical path of the microlens 25L.

In addition, in the present modification example, in addition to the reduced portion in the collection optical path of the microlens 25L, for example, the reduced portion 13X2 is provided in the intersection portion between the first separation section 13 and the second separation section 14. This makes it possible to enlarge an effective pixel region.

Furthermore, in the present modification example, the reduced portions 13X1 and 13X2 are provided in an intersection portion between the first separation sections 13 and the intersection portion between the first separation section 13 and the second separation section 14. As a result, it is possible to reduce a depth difference, caused by a microloading effect, between the intersection portion between the first separation sections 13 or the intersection portion between the first separation section 13 and the second separation section 14 and a point other than the intersection portion.

### 2-12. Modification Example 12

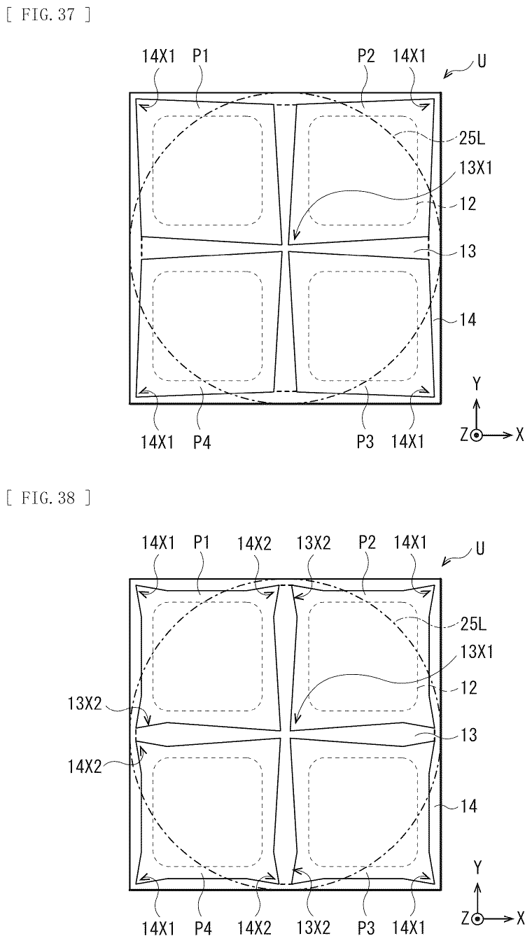

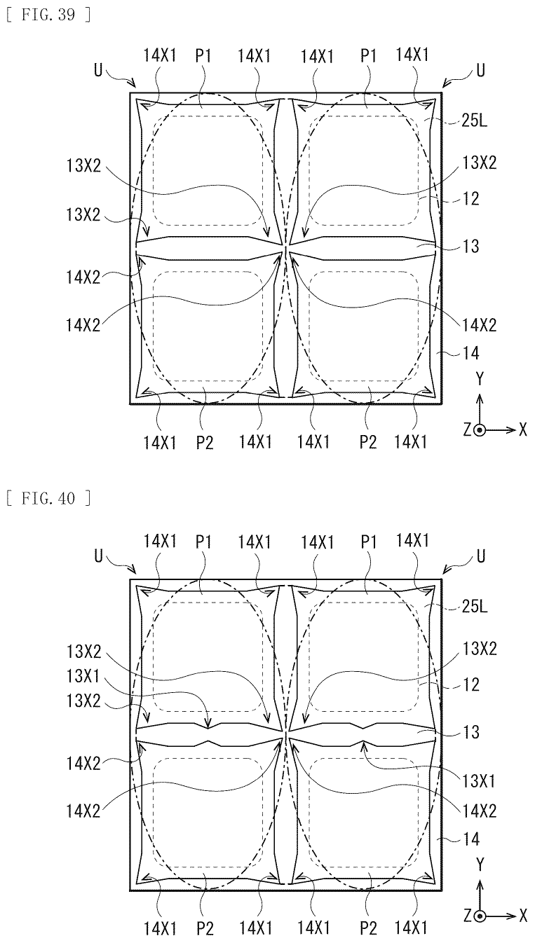

FIG. 36 schematically illustrates an example of a planar configuration of a photodetector according to Modification Example 12 of the present disclosure. FIG. 37 schematically illustrates another example of the planar configuration of the photodetector according to Modification Example 12 of the present disclosure. FIG. 38 schematically illustrates another example of the planar configuration of the photodetector according to Modification Example 12 of the present disclosure.

The second separation section 14 that separates the adjacent pixel units U from each other may have a reduced portion (for example, a reduced portion 14X1) having a line width reduced smaller than that of another portion in plan view.

Specifically, for example, as illustrated in FIGS. 36 and 37, in the second separation section 14 provided outside the pixel unit U including the unit pixels P1, P2, P3, and P4 arranged in two rows and two columns in the X-axis direction (the row direction) and the Y-axis direction (the column direction), the reduced portion 14X1 having a line width reduced smaller than that of another portion may be provided in an intersection portion between the second separation sections 14 that separate the adjacent pixel units U from each other in plan view.

In addition, a reduced portion of the second separation section 14 may be provided at a position other than the intersection portion between the second separation sections 14. For example, as illustrated in FIG. 38, a reduced portion 14X2 may be further provided in an intersection portion between the second separation section 14 and the first separation section 13.

Thus, in the present modification example, the reduced portions 14X1 and 14X2 are provided in the intersection portion between the second separation sections 14 and the intersection portion between the first separation section 13 and the second separation section 14. This makes it possible to enlarge the effective pixel region. In addition, it is possible to reduce a depth difference, caused by a microloading effect, between the intersection portion between the second separation sections 14 or the intersection portion between the first separation section 13 and the second separation section 14 and a point other than the intersection portion.

### 2-13. Modification Example 13

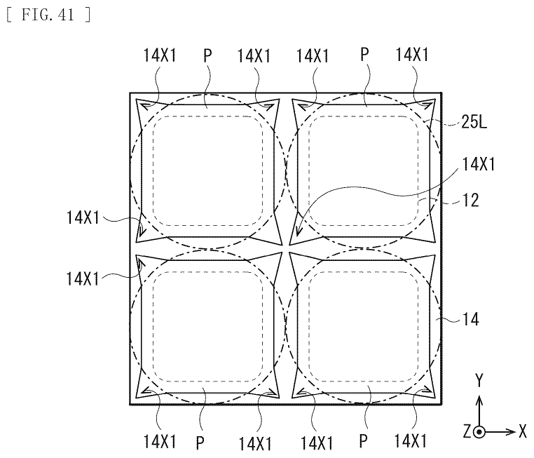

FIG. 39 schematically illustrates an example of a planar configuration of a photodetector according to Modification Example 13 of the present disclosure. FIG. 40 schematically illustrates another example of the planar configuration of the photodetector according to Modification Example 13 of the present disclosure.

In Modification Examples 11 and 12 described above, an example has been described in which, in the pixel unit U including the unit pixels P1, P2, P3, and P4 arranged in two rows and two columns, reduced portions (for example, the reduced portions 13X1, 13X2, 14X1, and 14X2) are provided in the first separation section 13 and the second separation section 14, but this is not limitative.

For example, as illustrated in FIG. 39, in the pixel unit U including the unit pixels P1 and P2 that are adjacent to each other in the Y-axis direction and share one microlens 25L, a reduced portion 13X2 may be provided in an intersection portion between the first separation section 13 that separates the adjacent unit pixels P1 and P2 from each other and the second separation section 14 that separates the adjacent pixel units U from each other. In addition, a reduced portion 14X1 may be provided in the intersection portion between the second separation sections 14.

In addition, as illustrated in FIG. 40, the reduced portion 13X1 may be provided in the first separation section 13 in the collection optical path of the microlens 25L shared by the unit pixels P1 and P2 adjacent to each other in the Y-axis direction.

In such a configuration also, it is possible to achieve effects similar to those in Modification Examples 11 and 12 described above.

Furthermore, in FIGS. 39 and 40, an example has been described in which two unit pixels P1 and P2 share one microlens 25L, but this is not limitative. For example, as illustrated in FIG. 41, also in a photodetector in which one microlens 25L is provided for each unit pixel P, providing the reduced portion 14X1 in the second separation section 14 makes it possible to enlarge the effective pixel region. In addition, it is possible to reduce a depth difference, caused by a microloading effect, at a point other than the intersection portion between the second separation sections 14.

### 2-14. Modification Example 14

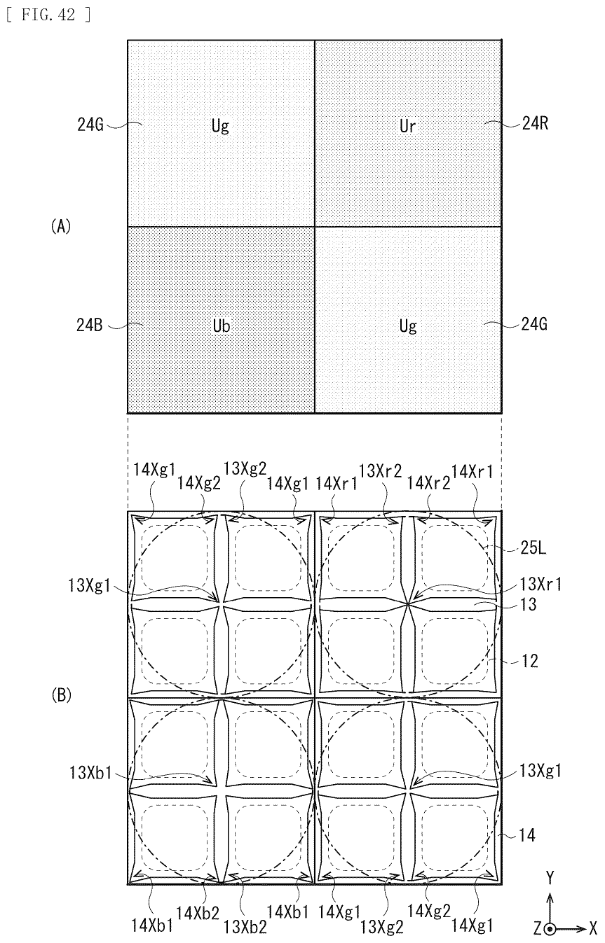

FIG. 42 illustrates arrangement of color filters (A) and an example of planar configurations of separation sections (B) in a photodetector according to Modification Example 14 of the present disclosure.

A reduction ratio of a line width of each of reduced portions (for example, the reduced portions 13X1, 13X2, 14X1, and 14X2) provided in the first separation section 13 and the second separation section 14 may be changed in accordance with a spectral characteristic of the color filter layer 24 provided above the reduced portions.

For example, as the reduced portion 13X1 of the first separation section 13 provided in the collection optical path of the microlens 25L is provided lower than the color filter layer 24 that allows color light of a long wavelength to pass therethrough, the reduction ratio thereof may become larger. Specifically, as illustrated in FIG. 42, a configuration may be adopted in which, of reduced portions 13Xr1, 13Xg1, and 13Xb1 of pixel units Ur, Ug, and Ub provided with the red color filter layer 24R that allows red light (R) to selectively pass therethrough, the green color filter layer 24G that allows green light (G) to selectively pass therethrough, and the blue color filter layer 24B that allows blue light (B) to selectively pass therethrough, the reduced portion 13Xr1 has the largest reduction ratio, the reduced portion 13Xg1 has the second largest reduction ratio, and the reduction portion 13Xb1 has the smallest reduction ratio. Alternatively, the reduced portion 13Xb1 may not be provided in the first separation section 13 of the pixel unit Ub.

For example, as the reduced portions 13X2, 14X1, and 14X2 provided in a portion other than the collection optical path of the microlens 25L, for example, in the intersection portion between the first separation section 13 and the second separation section 14, the intersection portion between the second separation sections 14, and the intersection portion between the second separation section 14 and the first separation section 13 are provided lower than the color filter layer 24 that allows color light of a short wavelength to pass therethrough, the reduction ratio thereof may become larger. Specifically, as illustrated in FIG. 42, a configuration may be adopted in which, of reduced portions 13Xr2, 13Xg2, 13Xb2, 14Xr1, 14Xg1, 14Xb1, 14Xr2, 14Xg2, and 14Xb2 of the pixel units Ur, Ug, and Ub provided with the red color filter layer 24R that allows red light (R) to selectively pass therethrough, the green color filter layer 24G that allows green light (G) to selectively pass therethrough, and the blue color filter layer 24B that allows blue light (B) to selectively pass therethrough, the reduced portions 13Xb2, 14Xb1, and 14Xb2 have the largest reduction ratio, the reduced portions 13Xg2, 14Xg1, and 14Xg2 have the second largest reduction ratio, and the reduced portions 13Xr2, 14Xr1, and 14Xr2 have the smallest reduction ratio. Alternatively, the reduced portions 13Xr2, 14Xr1, and 14Xr2 may not be provided in the second separation section 14 of the pixel unit Ur.

As a result, it is possible to efficiently suppress color mixture in the collection optical path of the microlens 25L. In addition, it is possible to enlarge the effective pixel region. Further, it is possible to efficiently reduce a depth difference, caused by a microloading effect, between the intersection between the first separation sections 13, the intersection portion between the first separation section 13 and the second separation portion 14, or the intersection portion between the second separation sections 14 and a point other than the intersection portion.

### 3. APPLICATION EXAMPLE

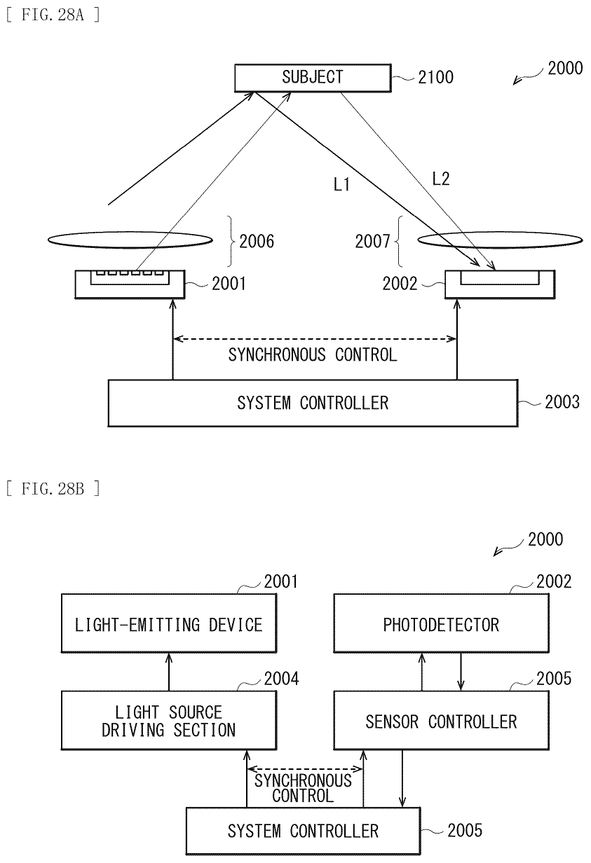

FIG. 28A schematically illustrates an example of an overall configuration of a photodetection system 2000 including a photodetector (for example, the photodetector 1). FIG. 28B illustrates an example of a circuit configuration of the photodetection system 2000. The photodetection system 2000 includes a light-emitting device 2001 as a light source section that emits infrared light L2, and a photodetector 2002 as a light-receiving section. As the photodetector 2002, for example, it is possible to use the photodetector 1 described above. The photodetection system 2000 may further include a system controller 2003, a light source driving section 2004, a sensor controller 2005, a light source-side optical system 2006, and a camera-side optical system 2007.

The photodetector 2002 is able to detect the light L1 and the light L2. The light L1 is ambient light from outside reflected by a subject (a measurement object) 2100 (FIG. 28A). The light L2 is light emitted from the light-emitting device 2001 and then reflected by the subject 2100. The light L1 is, for example, visible light, and the light L2 is, for example, infrared light. The light L1 is detectable by a photoelectric converter in the photodetector 2002, and the light L2 is detectable by a photoelectric conversion region in the photodetector 2002. It is possible to obtain image information of the subject 2100 from the light L1 and obtain distance information between the subject 2100 and the photodetection system 2000 from the light L2. It is possible to mount the photodetection system 2000 on, for example, an electronic apparatus such as a smartphone and a mobile body such as a car. It is possible to configure the light-emitting device 2001 with, for example, a semiconductor laser, a surface-emitting semiconductor laser, or a vertical cavity surface emitting laser (VCSEL). As a method of detecting the light L2 emitted from the light-emitting device 2001 by the photodetector 2002, for example, it is possible to adopt an iTOF method; however, the method is not limited thereto. In the iTOF method, the photoelectric converter is able to measure a distance to the subject 2100 by time of flight (Time-of-Flight; TOF), for example. As a method of detecting the light L2 emitted from the light-emitting device 2001 by the photodetector 2002, it is possible to adopt, for example, a structured light method or a stereovision method. For example, in the structured light method, light of a predetermined pattern is projected on the subject 2100, and distortion of the pattern is analyzed, thereby making it possible to measure the distance between the photodetection system 2000 and the subject 2100. In addition, in the stereovision method, for example, two or more cameras are used to obtain two or more images of the subject 2100 viewed from two or more different viewpoints, thereby making it possible to measure the distance between the photodetection system 2000 and the subject. It is to be noted that it is possible to synchronously control the light-emitting device 2001 and the photodetector 2002 by the system controller 2003.

### 4. PRACTICAL APPLICATION EXAMPLES

### Practical Application Example to Mobile Body

The technology according to the present disclosure is applicable to various products. For example, the technology according to the present disclosure may be achieved in the form of an apparatus to be mounted to a mobile body of any kind such as an automobile, an electric vehicle, a hybrid electric vehicle, a motorcycle, a bicycle, a personal mobility, an airplane, a drone, a vessel, or a robot.

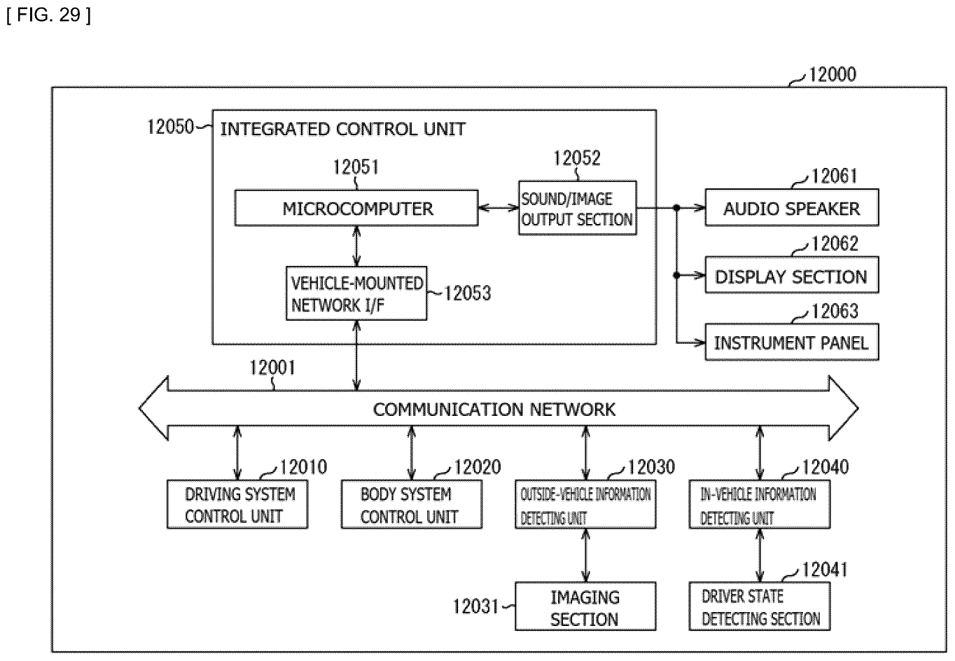

FIG. 29 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 29, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 29, an audio speaker 12061, a display section 12062, and an instrument panel 12063 are illustrated as the output device. The display section 12062 may, for example, include at least one of an on-board display and a head-up display.

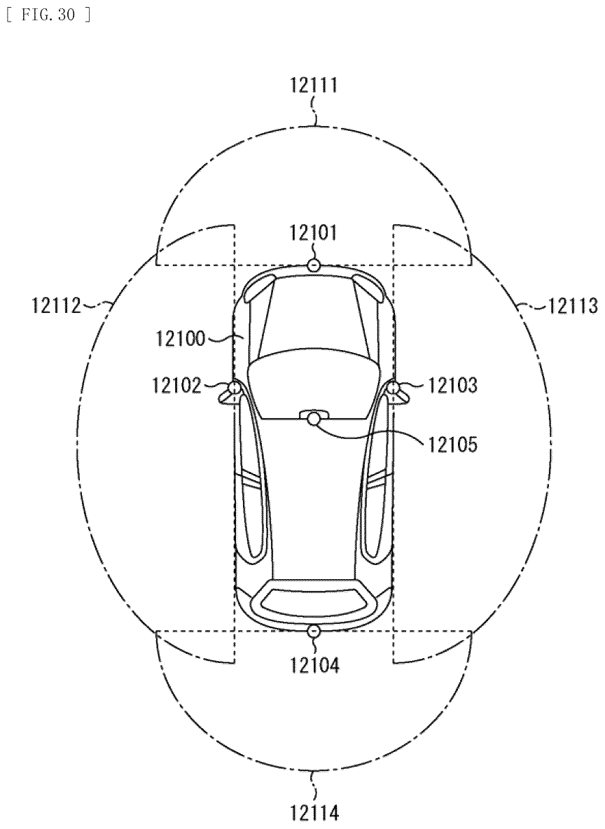

FIG. 30 is a diagram depicting an example of the installation position of the imaging section 12031.

In FIG. 30, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 30 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

One example of the vehicle control system to which the technology according to the present disclosure is applicable has been described above. The technology according to the present disclosure is appliable to the imaging section 12031 among the configurations described above. Specifically, an imaging device 100 is applicable to the imaging section 12031. Applying the technology according to the present disclosure to the imaging section 12031 makes it possible to obtain a high-definition shot image with less noise. This makes it possible to perform highly accurate control with use of the shot image in the mobile body control system.

### (Practical Application Example to Endoscopic Surgery System)

The technology according to the present disclosure (present technology) is applicable to various products. For example, the technology according to the present disclosure may be applied to an endoscopic surgery system.

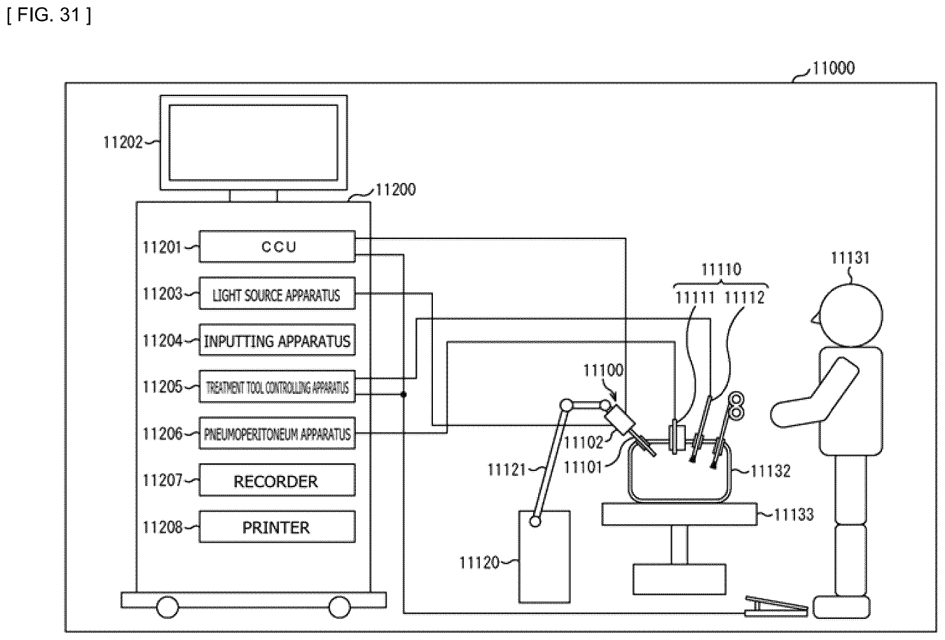

FIG. 31 is a view depicting an example of a schematic configuration of an endoscopic surgery system to which the technology according to an embodiment of the present disclosure (present technology) can be applied.

In FIG. 31, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

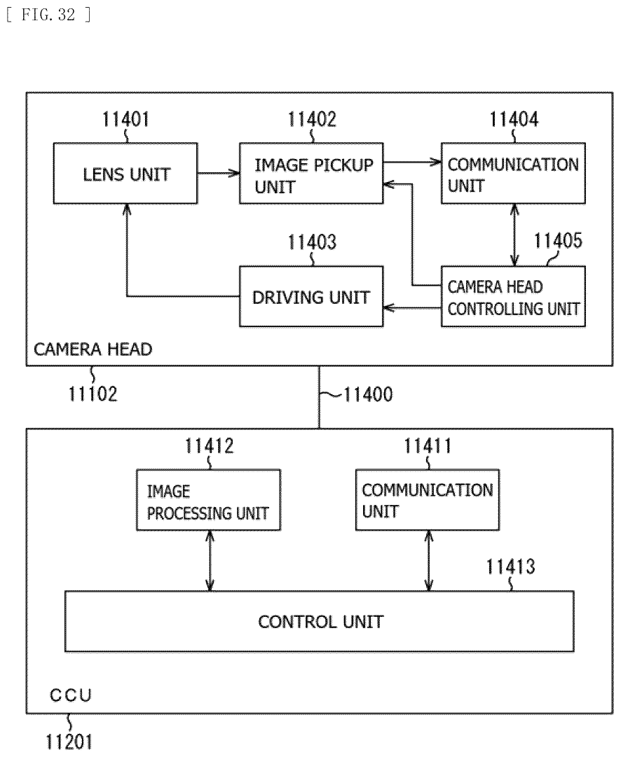

FIG. 32 is a block diagram depicting an example of a functional configuration of the camera head 11102 and the CCU 11201 depicted in FIG. 31.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

One example of the endoscopic surgery system to which the technology according to the present disclosure is applicable has been described above. The technology according to the present disclosure is suitably applicable to the image pickup unit 11402 provided in the camera head 11102 of the endoscope 11100 among the configurations described above. Applying the technology according to the present disclosure to the image pickup unit 11402 makes it possible to achieve downsizing or higher definition of the image pickup unit 11402 and it is thus possible to provide the small or high-definition endoscope 11100.

Although the present disclosure has been described above with reference to the embodiment, Modification Examples 1 to 14, and the practical application examples, the present technology is not limited to the embodiment described above and the like, and may be modified in a variety of ways. For example, respective members included in the photodetector (the photodetector 1) according to the embodiment described above or the like may be omitted as appropriate, or any other member may be provided. For example, an example has been described in which the light-shielding film 23 is provided on the second separation section 14, but the light-shielding film 23 may be omitted.

It is to be noted that the effects described herein are merely exemplary and are not limited to the description, and may further include other effects.

It is to be noted that the present disclosure may also have the following configurations. According to the present technology having the following configurations, a plurality of microlenses each extending over multiple pixels adjacent to each other is disposed on a light-receiving surface (a first surface) of a semiconductor substrate that includes a plurality of pixels arranged in a matrix and a photoelectric converter for each pixel, and a plurality of scatterers having different refractive indices is stacked on a collection optical path of each of the plurality of microlenses. This suppresses strong scattering of incident light by the scatterer provided closer to side of the light-receiving surface of the semiconductor substrate. Accordingly, it is possible to suppress color mixture while correcting deviation in a sensitivity difference between the multiple pixels sharing the microlens.

(1)

A photodetector including:
a semiconductor substrate having a first surface and a second surface opposed to each other, and including a plurality of pixels and a photoelectric converter, the plurality of pixels arranged in a matrix, and the photoelectric converter that is formed for each of the pixels to be embedded in the semiconductor substrate, and generates an electric charge corresponding to an amount of received light by photoelectric conversion;
a microlens disposed on side of the first surface to extend over adjacent pixels of the plurality of pixels; and
a plurality of scatterers having different indices, the plurality of scatterers stacked in a collection optical path of the microlens.
   (2)

The photodetector according to (1), in which
the plurality of scatterers includes a first scatterer and a second scatterer disposed in the collection optical path in order from side of the semiconductor substrate, and
scattering at an interface between the second scatterer and the first scatterer is smaller than scattering at an interface between the first scatterer and the semiconductor substrate.
   (3)

The photodetector according to (2), further including a first separation section that is embedded in the semiconductor substrate, and separates multiple pixels sharing the microlens, in which
the first scatterer is embedded in the first separation section, and
the second scatterer is disposed above the first separation section on side of the first surface of the semiconductor substrate.
   (4)

The photodetector according to (2) or (3), in which the second scatterer has a rectangular shape,
a triangular shape having a vertex on side of the microlens, or a trapezoidal shape expanding toward the microlens.
   (5)

The photodetector according to (3) or (4), in which a part of the second scatterer is embedded in the first separation section.

(6)

The photodetector according to any one of (3) to (5), further including a color filter layer provided between the first surface and the microlens, and including a plurality of color filters each having a spectral characteristic different for a plurality of the microlenses.

(7)

The photodetector according to (6), in which the second scatterer is disposed between the first surface and the color filter layer.

(8)

The photodetector according to (6) or (7), further including an intermediate layer provided between the first surface of the semiconductor substrate and the color filter layer, in which
the second scatterer is embedded in the intermediate layer.
   (9)

The photodetector according to (8), in which a part of the second scatterer is projected into the color filter layer.

(10)

The photodetector according to (6), in which the second scatterer is provided in the color filter layer.

(11)

The photodetector according to (6), in which the second scatterer is provided closer to the microlens than to the color filter layer.

(12)

The photodetector according to any one of (6) to (11), in which t the second scatterer has a height differing in accordance with the spectral characteristics of the plurality of color filters.

(13)

The photodetector according to any one of (2) to (12), in which the plurality of scatterers further includes a third scatterer provided above the second scatterer and having a refractive index different from refractive indices of the first scatterer and the second scatterer.

(14)

The photodetector according to any one of (1) to (13), in which
of the plurality of pixels, adjacent pixels sharing one of the microlenses are regarded as a pixel unit, and
the photodetector further includes a second separation section that is embedded in the semiconductor substrate and separates adjacent ones of the pixel units from each other.
   (15)

The photodetector according to (14), further including a light-shielding film provided above the second separation section on side of the first surface of the semiconductor substrate.

(16)

The photodetector according to (15), in which a part of the light-shielding film is embedded in the second separation section.

(17)

The photodetector according to any one of (6) to (16), further including a partition wall that separates the plurality of color filters having different spectral characteristics from each other.

(18)

The photodetector according to any one of (1) to (17), further including a wiring layer on side of the second surface of the semiconductor substrate.

(19)

The photodetector according to claim 1, in which
of the plurality of pixels, adjacent pixels sharing the microlens are regarded as a pixel unit, and
the photodetector further includes
a first separation section that is embedded in the semiconductor substrate, and separates the adjacent pixels in the pixel unit from each other,
a second pixel separation section that is embedded in the semiconductor substrate, and separates adjacent ones of the pixel units from each other, and
at least one of the first separation section or the second separation section has a reduced portion in which a line width of the first separation section or the second separation section is reduced in plan view.
   (20)

The photodetector according to claim 19, in which the first separation section has a first reduced portion as the reduced portion.

(21)

The photodetector according to claim 20, in which the first reduced portion is provided in a collection optical path of the microlens in plan view.

(22)

The photodetector according to claim 21, in which, in the first reduced portion, a line width of the first reduced portion is gradually reduced toward the collection optical path of the microlens in plan view from an intersection portion between the first separation section and the second separation section.

(23)

The photodetector according to claim 20, in which
the pixel unit includes four pixels arranged in two rows and two columns, and
the first reduced portion is provided in an intersection portion of the first separation section that separates the adjacent four pixels in the pixel unit from each other.
   (24)

The photodetector according to claim 23, in which the first reduced portion is further provided in an intersection portion with the second separation section.

(25)

The photodetector according to claim 20, further including a color filter layer provided between the first surface and the microlens, and including a plurality of color filters each having a spectral characteristic different for a plurality of the microlenses, in which
the first reduced portion has a different reduction ratio of a line width of the first separation section in accordance with the spectral characteristic of the color filter provided above the first reduced portion.
   (26)

The photodetector according to claim 19, in which the second separation section has a second reduced portion as the reduced portion.

(27)

The photodetector according to claim 26, in which
four pixel units arranged in two rows and two columns are included, and
the second reduced portion is provided in an intersection portion of the second separation section that separates the four pixel units from each other.
   (28)

The photodetector according to claim 27, in which, in the second reduced portion, a line width of the second separation section is gradually reduced toward an intersection portion of the four pixels from an intersection portion between the first separation section and the second separation section.

(29)

The photodetector according to claim 27, in which
the pixel unit includes four pixels arranged in two rows and two columns, and
the second reduced portion is further provided in an intersection portion with the first separation section that separates the adjacent four pixels in the pixel unit from each other.
   (30)

The photodetector according to claim 26, further including a color filter layer provided between the first surface and the microlens, and including a plurality of color filters each having a spectral characteristic different for a plurality of the microlenses, in which
the second reduced portion has a reduction ratio of a line width of the second separation section in accordance with the spectral characteristic of the color filter provided above the second reduced portion.
   (31)

An electronic apparatus including a photodetector, in which
the photodetector includes
a semiconductor substrate having a first surface and a second surface opposed to each other, and including a plurality of pixels and a photoelectric converter, the plurality of pixels arranged in a matrix, and the photoelectric converter that is formed for each of the pixels to be embedded in the semiconductor substrate, and generates an electric charge corresponding to an amount of received light by photoelectric conversion,
a microlens disposed on side of the first surface to extend over adjacent pixels of the plurality of pixels, and
a plurality of scatterers having different indices, the plurality of scatterers stacked in a collection optical path of the microlens.
   (32)

A photodetector including:
a semiconductor substrate having a first surface and a second surface opposed to each other, and including a plurality of pixels and a photoelectric converter, the plurality of pixels arranged in a matrix, and the photoelectric converter that is formed for each of the pixels to be embedded in the semiconductor substrate, and generates an electric charge corresponding to an amount of received light by photoelectric conversion; and
a separation section that is embedded in the semiconductor substrate and separates adjacent pixels of the plurality of pixels from each other, the separation section including a reduced portion in which a line width of at least a part is narrower than a line width of another part in plan view.
   (33)

The photodetector according to (32), in which the reduced portion is provided in at least a part of an intersection portion between the adjacent pixels of the plurality of pixels.

(34)

The photodetector according to (32) or (33), in which one microlens is disposed for each of the pixels on side of the first surface of the semiconductor substrate.

(35)

The photodetector according to (32) or (33), in which one microlens is disposed for every multiple pixels of the plurality of pixels on side of the first surface of the semiconductor substrate.

(36)

The photodetector according to (35), in which the reduced portion is formed in the separation section provided in a collection optical path of the microlens in plan view.

The present application claims the benefit of Japanese Priority Patent Application JP2022-143430 filed with the Japan Patent Office on Sep. 9, 2022, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A photodetector comprising:
a semiconductor substrate having a first surface and a second surface opposed to each other, and including a plurality of pixels and a photoelectric converter, the plurality of pixels arranged in a matrix, and the photoelectric converter that is formed for each of the pixels to be embedded in the semiconductor substrate, and generates an electric charge corresponding to an amount of received light by photoelectric conversion;
a microlens disposed on side of the first surface to extend over adjacent pixels of the plurality of pixels; and
a plurality of scatterers having different indices, the plurality of scatterers stacked in a collection optical path of the microlens.

2. The photodetector according to claim 1, wherein
the plurality of scatterers includes a first scatterer and a second scatterer disposed in the collection optical path in order from side of the semiconductor substrate, and
scattering at an interface between the second scatterer and the first scatterer is smaller than scattering at an interface between the first scatterer and the semiconductor substrate.

3. The photodetector according to claim 2, further comprising a first separation section that is embedded in the semiconductor substrate, and separates multiple pixels sharing the microlens, wherein
the first scatterer is embedded in the first separation section, and
the second scatterer is disposed above the first separation section on side of the first surface of the semiconductor substrate.

4. The photodetector according to claim 2, wherein the second scatterer has a rectangular shape, a triangular shape having a vertex on side of the microlens, or a trapezoidal shape expanding toward the microlens.

5. The photodetector according to claim 3, wherein a part of the second scatterer is embedded in the first separation section.

6. The photodetector according to claim 3, further comprising a color filter layer provided between the first surface and the microlens, and including a plurality of color filters each having a spectral characteristic different for a plurality of the microlenses.

7. The photodetector according to claim 6, wherein the second scatterer is disposed between the first surface and the color filter layer.

8. The photodetector according to claim 6, further comprising an intermediate layer provided between the first surface of the semiconductor substrate and the color filter layer, wherein
the second scatterer is embedded in the intermediate layer.

9. The photodetector according to claim 8, wherein a part of the second scatterer is projected into the color filter layer.

10. The photodetector according to claim 6, wherein the second scatterer is provided in the color filter layer.

11. The photodetector according to claim 6, wherein the second scatterer is provided closer to the microlens than to the color filter layer.

12. The photodetector according to claim 6, wherein the second scatterer has a height differing in accordance with the spectral characteristics of the plurality of color filters.

13. The photodetector according to claim 2, wherein the plurality of scatterers further includes a third scatterer provided above the second scatterer and having a refractive index different from refractive indices of the first scatterer and the second scatterer.

14. The photodetector according to claim 1, wherein
of the plurality of pixels, adjacent pixels sharing one of the microlenses are regarded as a pixel unit, and
the photodetector further comprises a second separation section that is embedded in the semiconductor substrate and separates adjacent ones of the pixel units from each other.

15. The photodetector according to claim 14, further comprising a light-shielding film provided above the second separation section on side of the first surface of the semiconductor substrate.

16. The photodetector according to claim 15, wherein a part of the light-shielding film is embedded in the second separation section.

17. The photodetector according to claim 6, further comprising a partition wall that separates the plurality of color filters having different spectral characteristics from each other.

18. The photodetector according to claim 1, further comprising a wiring layer on side of the second surface of the semiconductor substrate.

19. An electronic apparatus comprising a photodetector, wherein
the photodetector includes
a semiconductor substrate having a first surface and a second surface opposed to each other, and including a plurality of pixels and a photoelectric converter, the plurality of pixels arranged in a matrix, and the photoelectric converter that is formed for each of the pixels to be embedded in the semiconductor substrate, and generates an electric charge corresponding to an amount of received light by photoelectric conversion,
a microlens disposed on side of the first surface to extend over adjacent pixels of the plurality of pixels, and
a plurality of scatterers having different indices, the plurality of scatterers stacked in a collection optical path of the microlens.
